(19) United States
(12) Patent Application Publication
(10) Pub. No.: US 2025/0294993 A1
(43) Pub. Date: Sep. 18, 2025

(54) LIGHT-EMITTING APPARATUS

(71) Applicant: CANON KABUSHIKI KAISHA, Tokyo (JP)

(72) Inventors: TAKAHIRO AKIYAMA, Kanagawa (JP); HIROMASA TSUBOI, Tokyo (JP)

(21) Appl. No.: 19/061,735

(22) Filed: Feb. 24, 2025

(30) Foreign Application Priority Data
Mar. 12, 2024 (JP) 2024-038092

(51) Int. Cl. H10K 59/35; G02B 27/01; H10K 59/121; H10K 59/123; H10K 59/65

(52) U.S. Cl. CPC H10K 59/353; G02B 27/0172; H10K 59/1213; H10K 59/123; H10K 59/352; H10K 59/65; G02B 2027/0138; G02B 2027/0178

(57) ABSTRACT

A light-emitting apparatus according to an aspect of the embodiments is configured such that the gates of the drive transistors of adjacent subpixels are arranged so as not to overlap in a first direction, and in subpixels adjacent to the subpixels in a second direction, the gates of the drive transistors are arranged so as not to overlap in the first direction.

### BACKGROUND

### Technical Field

The aspect of the embodiments relates to light-emitting apparatuses, for example, a light-emitting apparatus including organic electroluminescence (EL) elements.

### Description of the Related Art

Japanese Patent Laid-Open No. 2022-16421 discloses a display apparatus including a drive-circuit array substrate including drive circuits arrayed on a semiconductor substrate and light-emitting elements arrayed above the drive circuits and driven by the drive circuits. Japanese Patent Laid-Open No. 2022-16421 discloses achieving higher definition of the drive circuit array by providing the substrate's well taps of the substrate in part of multiple drive circuits.

With the miniaturization of pixels in the light-emitting apparatus, it becomes necessary to arrange the transistors of the pixel drive circuits within a smaller area. However, Japanese Patent Laid-Open No. 2022-16421 does not address the arrangement of the transistors.

### SUMMARY

A light-emitting apparatus according to an aspect of the embodiments includes: a plurality of pixels each including a plurality of subpixels, wherein the plurality of pixels includes a first pixel and a second pixel adjacent to each other in a first direction and a third pixel and a fourth pixel adjacent to each other in the first direction, wherein the first pixel and the second pixel are adjacent to the third pixel and the fourth pixel, respectively, in a second direction crossing the first direction, wherein the plurality of subpixels each includes: a light-emitting element disposed over a main surface of a substrate; a drive transistor connected to the light-emitting element; a write transistor connected to the drive transistor; and a first capacitive element disposed between a source or a drain and a gate of the drive transistor, wherein the plurality of subpixels each includes a first subpixel, a second subpixel, and a third subpixel disposed between the first subpixel and the second subpixel in the first direction, wherein, in each of the first subpixel and the second subpixel, the gate of the drive transistor in plan view of the main surface is larger than a gate of the write transistor in the plan view, wherein the first subpixel of the first pixel and the second subpixel of the second pixel are adjacent to each other in the first direction, wherein the first subpixel of the third pixel and the second subpixel of the fourth pixel are adjacent to each other in the first direction.

Further features of the disclosure will become apparent from the following description of exemplary embodiments with reference to the attached drawings.

### BRIEF DESCRIPTION OF THE DRAWINGS

FIG. 1 is a system chart illustrating an example of part of a light-emitting apparatus according to an embodiment.

FIG. 2 is a circuit diagram of an example of the subpixel of the light-emitting apparatus according to an embodiment.

FIG. 3 is a plan view of an example of a transistor according to an embodiment of the disclosure.

FIG. 4 is a plan view of an example of part of a light-emitting apparatus according to a first embodiment.

FIG. 5 is a plan view of an example of part of a light-emitting apparatus according to a second embodiment.

FIG. 6 is a circuit diagram of an example of the subpixel of a light-emitting apparatus according to a third embodiment.

FIG. 7 is a plan view of an example of part of the light-emitting apparatus according to the third embodiment.

FIG. 8 is a circuit diagram of an example of the subpixel of a light-emitting apparatus according to a fourth embodiment.

FIG. 9 is a plan view of an example of part of the light-emitting apparatus according to the fourth embodiment.

FIG. 10 is a plan view of an example of the outer edge of the subpixel in the upper layer of a light-emitting apparatus according to an embodiment.

FIG. 11 is a cross-sectional view of an example of part of the light-emitting apparatus according to the fourth embodiment.

FIG. 12 is a schematic cross-sectional view of an example of the pixels of a display apparatus according to a fifth embodiment.

FIG. 13 is a schematic diagram illustrating an example of the display apparatus according to the fifth embodiment.

FIG. 14A is a schematic diagram illustrating an example of an image capturing apparatus according to the fifth embodiment.

FIG. 14B is a schematic diagram illustrating an example of an electronic apparatus according to the fifth embodiment.

FIG. 15A is a schematic diagram illustrating an example of a display apparatus according to an embodiment.

FIG. 15B is a schematic diagram illustrating an example of a foldable display apparatus.

FIG. 16A is a schematic diagram illustrating an example of a wearable device according to an embodiment.

FIG. 16B is a schematic diagram of an example of a wearable device according to an embodiment, illustrating an embodiment including an image capturing apparatus.

### DESCRIPTION OF THE EMBODIMENTS

Light-emitting apparatuses according to the embodiments will be described hereinbelow with reference to the drawings. It is to be understood that the embodiments are merely examples of the present disclosure, and the numerical values, shapes, materials, components, the arrangement and connection configurations of the components do not limit the present disclosure.

### First Embodiment

The following description is made for a case where drive transistors are connected to the electrodes (in this case, anodes) of organic light-emitting elements, an example of light-emitting elements, and all the transistors are P-type transistors. However, the light-emitting apparatuses of this embodiment are not limited to this case. The polarity and conductivity type may all be reversed or some of them may be reversed. For example, the drive transistors may be P-type transistors, while the other transistors may be N-type transistors. The supplied potential and connections may be adjusted appropriately based on the conductivity type and polarity. The parts marked with the same reference signs in the drawings indicate identical or functionally similar components.

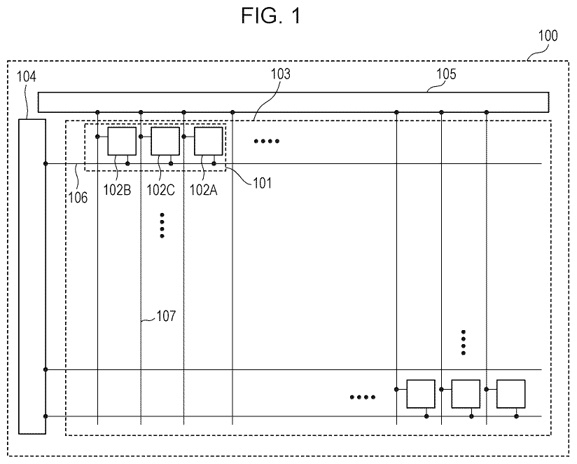

FIG. 1 is a system chart illustrating an overview of an example of part of a light-emitting apparatus 100 according to this embodiment. As illustrated in FIG. 1, an organic EL display apparatus, which is an example of the light-emitting apparatus 100, includes a pixel array section 103 and a drive section arranged around the pixel array section 103. The pixel array section 103 includes multiple pixels 101 arrayed two-dimensionally in rows and columns. Each pixel 101 includes multiple subpixels 102.

In this example, one pixel 101 includes a first subpixel 102A, a second subpixel 102B, and a third subpixel 102C disposed between the first subpixel 102A and the second subpixel 102B. In this specification, when a certain member or part is described in general terms, a reference sign is used, and when specific elements of that member or part are distinguished, letters such as A, B, etc., are appended to the reference sign.

The drive section is a circuit for driving each pixel 101 (subpixel 102). For example, the drive section includes a vertical scanning circuit 104 and a signal output circuit 105. In the pixel array section 103, first scanning lines 106 are arranged for the individual pixel rows along the row direction, and signal lines 107 are arranged for the individual pixel columns along the column direction.

Each first scanning line 106 is connected to the output terminal of the corresponding row in the vertical scanning circuit 104. Each signal line 107 is connected to the corresponding output terminal of the signal output circuit 105. In writing a video signal to each pixel 101 (subpixel 102) in the pixel array section 103, the vertical scanning circuit 104 supplies a write control signal to the first scanning lines 106. The signal output circuit 105 outputs a luminance signal having a voltage based on externally supplied digital display data.

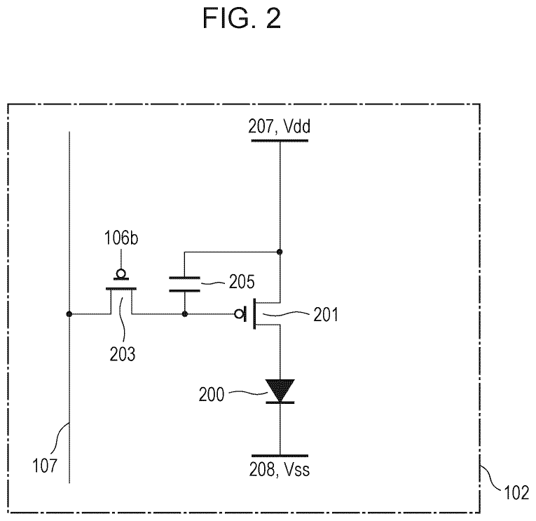

FIG. 2 is a circuit diagram of an example of the subpixel 102 of the light-emitting apparatus in FIG. 1. As illustrated in FIG. 2, the subpixel 102 includes a light-emitting element 200, such as an organic light-emitting element, a drive transistor 201, a write transistor 203, and a capacitive element 205. The light-emitting element 200 includes an organic layer including a light-emitting layer between an anode and a cathode. The organic layer may include, in addition to the light-emitting layer, one or more of a hole injection layer, a hole transport layer, an electron injection layer, and an electron transport layer.

The drive transistor 201 and the write transistor 203 are metal-oxide semiconductor field-effect transistors (MOSFETs). The control signal is input to the gate of the write transistor 203 through the scanning line 106b. The source of the drive transistor 201 is connected to a power supply line 207 (a first power supply line) for supplying a power source potential Vdd. One electrode (here, the cathode) of the light-emitting element 200 is connected to a power supply line 208 for supplying a power source potential Vss.

The signal line 107 is connected to the source of the write transistor 203. The voltage on the signal line 107 is input to the gate of the drive transistor 201 at the moment when the write transistor 203 switches to ON state.

The source-drain current value of the drive transistor 201 depends on the signal voltage, thereby controlling the emission luminance of the light-emitting element 200. The drain of the drive transistor 201 is connected to the anode of the light-emitting element 200. The capacitive element 205 (a first capacitive element) is connected between the gate and the source of the drive transistor 201.

In other words, in this embodiment, the subpixels 102 each include the light-emitting element 200 placed on the main surface of the substrate and the drive transistor 201 connected to the light-emitting element 200.

Each subpixel 102 further includes the write transistor 203 connected to the drive transistor 201 and the capacitive element 205 (first capacitive element) disposed between one of the source and the drain (here, the source) and the gate of the drive transistor 201.

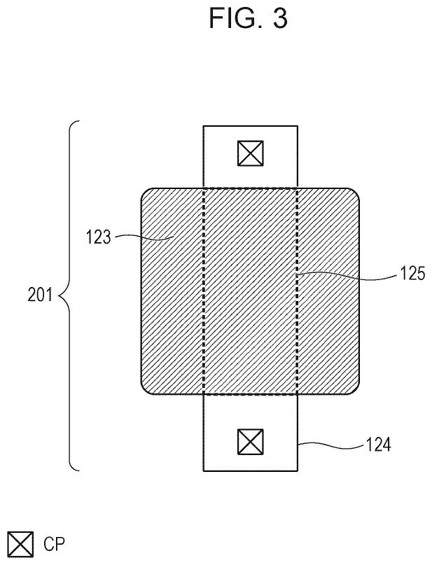

Referring to FIG. 3, the definition of the gate in this specification will be described. FIG. 3 is a top view of the MOSFET, which is an example of the transistors. In this specification, the gate 125 is a portion where a conductive layer 123 constituting the gate 125 and an active region 124 of the transistor overlap in plan view of the main surface of the substrate (the surface on which the light-emitting element 200 is disposed). The conductive layer 123 constituting the gate may be formed of, for example, polysilicon. One example of the substrate is a semiconductor substrate. The wiring lines, the electrodes, the semiconductor substrate, etc. may be connected via contact plugs CP as appropriate.

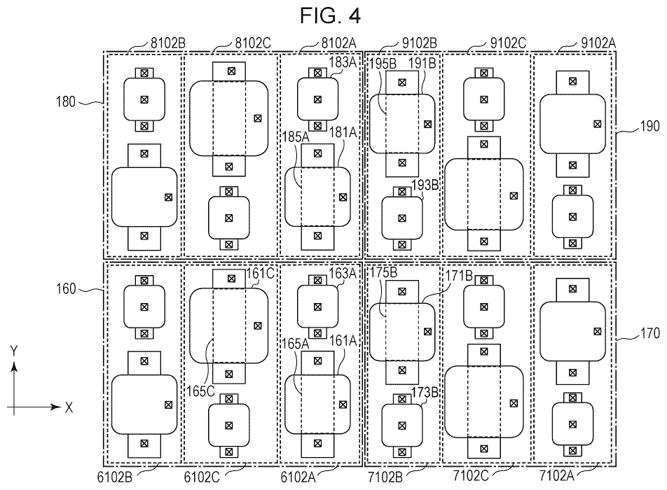

FIG. 4 is a plan view of the transistors of part of the pixel array section 103 in this embodiment. The pixel array section 103 includes multiple pixels 101. The multiple pixels 101 include a first pixel 160 and a second pixel 170 adjacent to each other in a first direction X and a third pixel 180 and a fourth pixel 190 adjacent to each other in the first direction X.

The first pixel 160 and the second pixel 170 are adjacent to the third pixel 180 and the fourth pixel 190, respectively, in a second direction Y intersecting the first direction X. In this example, the first direction X and the second direction Y intersect vertically. However, the arrangement of the pixels 101 of this embodiment is not limited to the above example.

The first pixel 160, the second pixel 170, the third pixel 180, and the fourth pixel 190 each include a first subpixel, a second subpixel, and a third subpixel. For the subpixels in the pixels, descriptions of similar parts will be omitted as appropriate.

The first pixel 160 includes a first subpixel 6102A, a second subpixel 6102B, and a third subpixel 6102C. The second pixel 170 includes a first subpixel 7102A, a second subpixel 7102B, and a third subpixel 7102C. The third pixel 180 includes a first subpixel 8102A, a second subpixel 8102B, and a third subpixel 8102C. The fourth pixel 190 includes a first subpixel 9102A, a second subpixel 9102B, and a third subpixel 9102C.

Here, the first subpixel 6102A of the first pixel 160 and the second subpixel 7102B of the second pixel 170 are adjacent to each other. The first subpixel 8102A of the third pixel 180 and the second subpixel 9102B of the fourth pixel 190 are adjacent to each other.

The following description is made mainly using the first pixel 160. The other pixels also have similar configurations, functions, materials, effects, etc., unless otherwise specified.

A drive transistor 161A and a write transistor 163A in the first subpixel of the first pixel 160 in FIG. 4 correspond to the drive transistor 201 and the write transistor 203 in FIG. 2, respectively.

The drive transistor 161A and the write transistor 163A are isolated by, for example, an insulator. Since the drain of the write transistor 163A and the gate 165A of the drive transistor 161A are electrically connected by wiring because they share the same node, as illustrated in the circuit diagram of FIG. 2. The gate 165A of the drive transistor 161A is larger than the gate of the write transistor 163A in plan view of the main surface of the substrate. The drive transistors and the write transistors constituting the pixel drive circuits of the other subpixels also have the same configuration relationship. In this specification, “member A is large in plan view” indicates that the area of the external form of the member A is large.

FIG. 4 is a plan view of the main surface of the substrate. A conductive layer (including polysilicon) serving as a gate electrode and a wiring layer are laminated on the substrate main surface. The pixel drive circuit of the subpixel 102 illustrated in FIG. 2 includes the electrodes, wiring lines, contact plugs, etc. In FIG. 4, part of the wire connection (lines and contact plugs) illustrated in the circuit diagram of FIG. 2 is omitted.

In this embodiment, the gate 165A of the drive transistor 161A of the first subpixel 6102A of the first pixel 160 and the gate 175B of the drive transistor 171B of the second subpixel of the second pixel 170 are arranged so as not to overlap with each other in the first direction X. The gate 185A of the drive transistor 181A of the first subpixel 8102A of the third pixel 180 and the gate 195B of the drive transistor 191B of the second subpixel 9102B of the fourth pixel 190 are arranged so as not to overlap with each other in the first direction X.

Thus, arranging the gates of the drive transistors with a large area so as not to overlap in the first direction X between the adjacent pixels in plan view of the substrate main surface allows the pixel drive circuits to be densely arranged within a small area.

Furthermore, considering production variations, in one embodiment, polysilicon elements have large space therebetween compared to the wiring lines. Therefore, the distance between the gates of the drive transistors formed from polysilicon is to be larger than the distance between the wiring lines. Thus, arranging the gates of the adjacent drive transistors not to overlap in the first direction X allows densely arranging the elements of the pixel drive circuits more effectively. In other words, even if the area of each pixel drive circuit is small, a sufficient distance between the gate of the drive transistor and the other elements can be ensured, thereby suppressing variations in subpixel characteristics caused by manufacturing processes, such as polysilicon processing variations of the gates.

Furthermore, also in the row having adjacent subpixels and the row of subpixels adjacent in the second direction Y, the gates of the drive transistors may be disposed not to overlap in the first direction X between the adjacent different pixels. This configuration enables the pixel drive circuits to be arranged more densely within a small area. Since the gates of the drive transistors in multiple pixel rows do not overlap in the first direction X, the transistors may be disposed densely, enabling the pixel drive circuits to be arranged densely within a smaller area.

The gates of the drive transistors of the adjacent subpixels in the first pixel 160 may be arranged not to overlap in the first direction X. For example, the gate 165A of the drive transistor 161A of the first subpixel 6102A and the gate 165C of the drive transistor 161C of the third subpixel 6102C are arranged not to overlap in the first direction X. This enables the pixel drive circuits of the subpixels to be arranged densely within a small area. This allows suppressing variations in characteristics caused by manufacturing processes, such as polysilicon processing variations of the gates.

Thus, in the multiple subpixels arranged in two-dimensional pattern, the gates of the drive transistors are arranged not to overlap in the first direction X in plan view of the substrate main surface (arranged in a staggered pattern). This enables the pixel drive circuits of the multiple subpixels to be arranged densely, thereby achieving the high definition and size-reduction of the light-emitting apparatus.

The use of the configuration of this embodiment enables the gates of the drive transistors of adjacent subpixels to be arranged most densely in each pixel and between pixels. The gates of the drive transistors make up a large proportion of the components in the pixel drive circuit in plan view.

Thus, by densely arranging the gates of the drive transistors, the pixel drive circuits may also be densely arranged. For the same area, a sufficient distance between the gates of the drive transistors and the other elements is ensured, thereby suppressing variations in the characteristics of the subpixels caused by the manufacturing process.

Referring to FIG. 4, the directions from the sources to the drains of the drive transistors arranged in the first pixel 160 and the second pixel 170 are the same direction. The directions from the sources to the drains of the drive transistors arranged in the third pixel 180 and the fourth pixel 190 are the same direction.

Furthermore, the directions from the sources to the drains of the drive transistors arranged in the first pixel 160 to fourth pixel 190 may be the same direction. This configuration allows reducing variations in the characteristics of the drive transistors.

### Second Embodiment

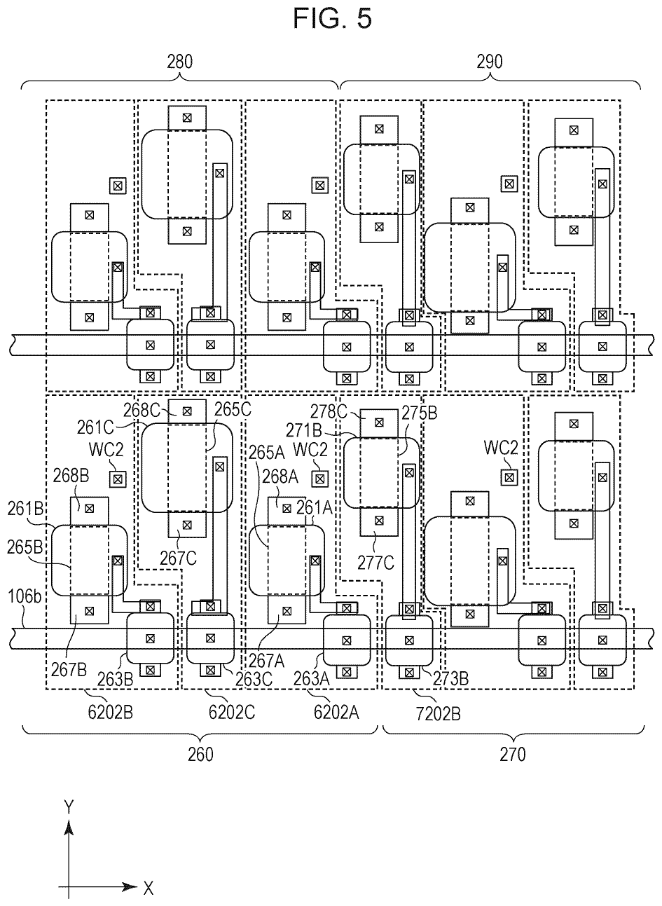

Referring to FIG. 5, another example of the subpixels of the light-emitting apparatus will be described. The same configurations, properties, functions, materials, and effects as those of the first embodiment will be omitted as appropriate.

FIG. 5 is a plan view of transistors of pixel drive circuits in this embodiment. A first pixel 260, a second pixel 270, a third pixel 280, and a fourth pixel 290 correspond to the first pixel 160, the second pixel 170, the third pixel 180, and the fourth pixel 190 of the first embodiment, respectively.

For example, the multiple pixels include the first pixel 260 and the second pixel 270 adjacent to each other in the first direction X and the third pixel 280 and the fourth pixel 290 adjacent to each other in the first direction X. The first pixel 260 and the second pixel 270 are respectively adjacent to the third pixel 280 and the fourth pixel 290 in the second direction Y intersecting the first direction X. The first direction X and the second direction Y may intersect at an angle less than 90° rather than at right angles.

The first pixel 260 includes a first subpixel 6202A, a second subpixel 6202B, and a third subpixel 6202C. The second pixel 270, the third pixel 280, and the fourth pixel 290 also each include a first subpixel, a second subpixel, and a third subpixel. A well potential is supplied to the semiconductor substrate through well contacts WC2.

For the subpixels within these pixels, descriptions of the similar parts will be omitted as appropriate. For the arrangement of the pixels, as well as the arrangement and configuration of the subpixels within the pixels, descriptions of parts similar to those in the first embodiment will be omitted as appropriate.

The following description is made mainly using the first pixel 260. The other pixels also have similar configurations, materials, properties, functions, effects, etc., unless otherwise specified.

A drive transistor 261A in FIG. 5 corresponds to the drive transistor 201 in FIG. 2 and the drive transistor 161A in FIG. 4. A write transistor 263A in FIG. 5 corresponds to the write transistor 203 in FIG. 2 and the write transistor 163A in FIG. 4.

The drive transistor 261A and the write transistor 263A are isolated by an insulator. The drain of the write transistor 263A and the gate 265A of the drive transistor 261A are electrically connected by wiring. One example of the substrate is a semiconductor substrate. A potential is supplied to the wells in the semiconductor substrate via the well contacts WC2. FIG. 5 is a plan view of the main surface of the substrate.

The first subpixel 6202A, the second subpixel 6202B, and the third subpixel 6202C of the first pixel 260 may have light-emitting elements of different colors. For example, the drive transistor 261A and the write transistor 263A may drive a light-emitting element that emits red light, the drive transistor 261B and the write transistor 263B may drive a light-emitting element that emits green light, and the drive transistor 261C and the write transistor 263C may drive a light-emitting element that emits blue light.

In the pixel drive circuit of each subpixel, the gate of the drive transistor is the largest in plan view. In FIG. 5, the gate of the drive transistor of the drive circuit of a subpixel and the gate of the drive transistor of the pixel drive circuit of the adjacent subpixel are arranged not to overlap in the first direction X. The gates of the drive transistors of the adjacent subpixels are arranged not to overlap in the first direction X, not only when the adjacent subpixels are within one pixel but also when they are in different pixels.

This allows the pixel drive circuits for driving the subpixels to be densely arranged in a small area. For the gates formed from polysilicon, a sufficient distance between the gates is ensured even if the area of the pixel drive circuits is small, as described in the first embodiment. Thus, variations in characteristics caused by manufacturing processes, such as polysilicon processing variations of the gates, can be suppressed.

Furthermore, also in the row having adjacent subpixels and the row of subpixels adjacent in the second direction Y, the gates of the drive transistors may be disposed not to overlap in the first direction X between the adjacent different pixels. This configuration enables the pixel drive circuits to be arranged more densely within a small area. Since the gates of the drive transistors in multiple pixel rows do not overlap in the first direction X, the transistors may be disposed densely, enabling the pixel drive circuits to be arranged densely within a smaller area.

Thus, in the multiple subpixels arranged in two-dimensional pattern, the gates of the drive transistors are arranged not to overlap in the first direction X in plan view of the substrate main surface (arranged in a staggered pattern). This enables the pixel drive circuits of the multiple subpixels to be arranged densely, thereby achieving the high definition and size-reduction of the light-emitting apparatus.

The configuration will be described more specifically. For example, in the first pixel 260, the drive transistor 261A of the first subpixel 6202A includes a gate 265A, and the drive transistor 261B of the second subpixel 6202B includes a gate 265B. The drive transistor 261C of the third subpixel 6202C disposed between the first subpixel 6202A and the second subpixel 6202B includes a gate 265C.

In this case, the gate 265A of the drive transistor 261A of the first subpixel 6202A and the gate 265C of the drive transistor 261C of the adjacent third subpixel 6202C are arranged at positions that do not overlap in the first direction X. The gate 265C of the drive transistor 261C of the third subpixel 6202C and the gate 265B of the drive transistor 261B of the adjacent second subpixel 6202B are arranged at positions that do not overlap in the first direction X.

In the second pixel 270 adjacent to the first pixel 260, a second subpixel 7202B adjacent to the first subpixel 6202A includes a drive transistor 271B, and the drive transistor 271B includes a gate 275B. In this case, the gate 265A of the drive transistor 261A of the first subpixel 6202A of the first pixel 260 and the gate 275B of the drive transistor 271B of the second subpixel 7202B of the adjacent second pixel 270 are arranged at positions that do no overlap in the first direction X. The other adjacent subpixels may have the same configuration, though the description is omitted here.

The directions from the sources to the drains of the drive transistors of the first pixel 260 to the fourth pixel 290 shown in FIG. 5 are the same direction. For example, the direction from the sources to the drains of the drive transistors of the first pixel 260 and the direction from the sources to the drains of the drive transistors of the second pixel 270 are the same direction. Here, the term “same direction” refers to a substantially identical direction, including cases where there may be slight deviations due to manufacturing errors or the like.

Specifically, the direction from the source 267A to the drain 268A of the drive transistor 261A and the direction from the source 267B to the drain 268B of the drive transistor 261B are the same. Similarly, the direction from the source 267A to the drain 268A of the drive transistor 261A and the direction from the source 267C to the drain 268C of the drive transistor 261C are the same. The direction from the source 267A to the drain 268A of the drive transistor 261A and the direction from the source 277C to the drain 278C of the drive transistor 271C are the same. The other adjacent subpixels may have the same configuration, though the description is omitted here.

Since the drive transistors of different subpixels are arranged so that the directions from the sources to the drains are the same, manufacturing variations are less likely to cause characteristic variations. Thus, this embodiment provides a configuration in which the transistors of the pixel drive circuits are arranged in a smaller area, and manufacturing variations are less likely to result in characteristic variations.

At least one of the width and length of the gate of the drive transistor 201 of one of the three subpixels of one subpixel in FIG. 5 may be larger than at least one of the width and length of the gates of the drive transistors of the other two subpixels.

For example, the light-emitting element is configured to emit light in three colors-read, green, and blue-within one pixel. Among these, the green light source is known to have high relative luminosity. Therefore, the variation characteristics of the green light source have a significant impact on the luminance variation characteristics of the light-emitting apparatus. By making at least one of the width and length of the gate of the drive transistor 201 of the subpixel that emits green light larger, the manufacturing variations can be suppressed.

In FIG. 5, the subpixel 6202C is a subpixel that emits green light, and the subpixel 6202A and the subpixel 6202B are subpixels that emit red or blue light. In the pixel 260, the width and length of the gate 265C of the drive transistor 261C are larger than the widths and lengths of the respective gates 265A and 265B of the drive transistors 261A and 261B of the other subpixels 6202A and 6202B.

This allows reducing the luminous variations of the light-emitting elements driven by the drive transistor 261C, thereby minimizing the luminance variations in the green subpixel, which has the greatest impact. This provides the effect of suppressing the luminance variation characteristics of the light-emitting apparatus. In contrast, the respective gates 265A and 265B of the drive transistors 261A and 261B of the subpixels 6202A and 6202B that emit blue or red light are smaller than the gate 265C of the drive transistor 261C, thereby preventing the pixel 260 from increasing in size.

However, in this embodiment, it is not necessary to dispose a pixel drive circuit having a drive transistor with the largest gate for the green light source. The pixel drive circuit may instead be disposed for a red light source or a blue light source. Alternatively, the widths and lengths of the gates of the drive transistors of the three subpixels may be all the same.

The widths and lengths of the gates of the drive transistors of the pixel drive circuits do not have to be the same among the subpixels, as described above. However, ensuring that the width-to-length ratios of the gates are equal allows the current-voltage characteristics of the transistors to be similar. This may reduce emission variations, etc. caused by the characteristic variations of the transistors of the subpixels. In this specification, the term “equal length” refers to a substantially equal length, including manufacturing errors.

In FIG. 5, the write transistor 263 is arranged so as to at least partly overlap with the write transistor 263 of the adjacent subpixel in the first direction X. For example, in the first pixel 260, the write transistor 263B of the second subpixel 6202B and the write transistor 263C of the third subpixel 6202C overlap at least partly in the first direction X. The write transistor 263A of the first subpixel 6202A and the write transistor 263C of the third subpixel 6202C overlap at least partly in the first direction X.

In this embodiment, the write transistors 263A, 263B, and 263C are operated with the same scanning line 106b. Thus, by arranging them so as to overlap at least partly in one direction, the integration efficiency is enhanced. Furthermore, since there is no need to route the scanning line 106b, the scanning line 106b can be arranged easily in minimal area with low resistance.

Having described about the first pixel 260, the above effects are provided also for the second pixel 270, the third pixel 280, and the fourth pixel 290 using the same configuration as shown in FIG. 5. The write transistor 263 of the first pixel 260 and the write transistor 273 of the second pixel 270 adjacent in the first direction X may be arranged at positions that overlaps at least partly in the first direction X. This may further enhance the forementioned effects.

### Third Embodiment

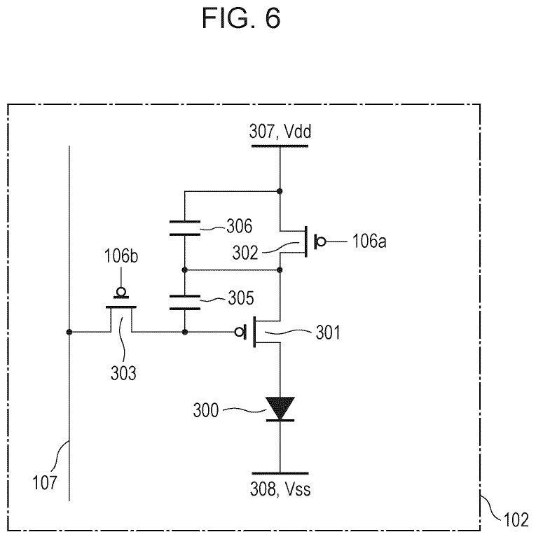

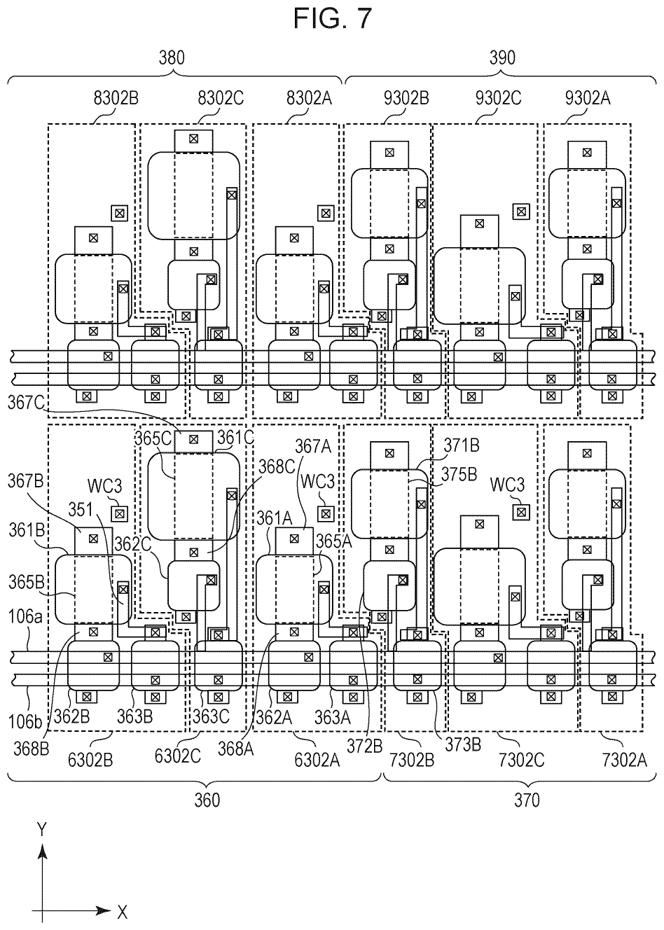

Referring to FIGS. 6 and 7, a light-emitting apparatus according to a third embodiment of the disclosure will be described. The same configurations, properties, materials, functions, and effects as those of the first or second embodiment will be omitted as appropriate.

FIG. 6 is a circuit diagram of a subpixel 102 in this embodiment. The subpixel 102 includes a light-emitting element 300, which is an organic light-emitting element, three transistors—a drive transistor 301, an emission control transistor 302, and a write transistor 303, a capacitive element 305, and a capacitive element 306. The three transistors may be MOSFETs. Control signals are input to the gates of the emission control transistor 302 and the write transistor 303 through two scanning lines 106a and 106b.

The signal line 107 connects to the source of the write transistor 303. When the write transistor 303 switches to ON state, the voltage on the signal line 107 is input to the gate of the drive transistor 301. The current that flows between the source and the drain of the drive transistor 301 depends on the signal voltage, thereby controlling the emission luminance of the light-emitting element 300. A potential determined by the photoelectric conversion characteristics of the light-emitting element 300 is supplied to power supply lines 307 and 308, with a potential difference of, for example, 7 V being applied between the power supply lines 307 and 308.

The subpixels of this embodiment each include the emission control transistor 302 and the capacitive element 306, in addition to the elements of the subpixels of the second embodiment. Accordingly, the description will be given with reference to the configuration of the second embodiment as appropriate for convenience of description.

In the subpixel 102 of FIG. 6, the drain of the emission control transistor 302 and the source of the drive transistor 301 have the same potential and share the same node. The drain of the write transistor 303 and the gate of the drive transistor 301 are connected by a wiring line 351 (FIG. 7).

FIG. 7 is a plan view of the main surface of the substrate, illustrating part of the electrodes and the wiring lines illustrated in FIG. 6, and contact plugs. The pixel circuit of the subpixel 102 shown in FIG. 6 includes a wiring layer on the main surface of the substrate and includes a wiring pattern (including, for example, metal and polysilicon) and contact plugs.

FIG. 7 is a plan view of the transistors of the pixel drive circuits in this embodiment. A first pixel 360, a second pixel 370, a third pixel 380, and a fourth pixel 390 correspond to the first pixel 260, the second pixel 270, the third pixel 280, and the fourth pixel 290 of the second embodiment, respectively.

For example, the multiple pixels include the first pixel 360 and the second pixel 370 adjacent to each other in the first direction X and the third pixel 380 and the fourth pixel 390 adjacent to each other in the first direction X. The first pixel 360 and the second pixel 370 are respectively adjacent to the third pixel 380 and the fourth pixel 390 in the second direction Y intersecting the first direction X. The first direction X and the second direction Y may intersect at an angle less than 90° rather than at right angles.

The first pixel 360 includes a first subpixel 6302A, a second subpixel 6302B, and a third subpixel 6302C. The second pixel 370, the third pixel 380, and the fourth pixel 390 also each include a first subpixel, a second subpixel, and a third subpixel. For the subpixels within these pixels, descriptions of the similar parts will be omitted as appropriate.

The following description will be made mainly using the first pixel 360. The other pixels also have the same configurations, materials, properties, functions, effects, etc. as those of the first pixel 360, unless otherwise specified.

A drive transistor 361A in FIG. 7 corresponds to the drive transistor 261A in FIG. 5. A write transistor 363A in FIG. 7 corresponds to the write transistor 263A in FIG. 5. For example, the drive transistor 301, the emission control transistor 302, and the write transistor 303 of the pixel drive circuit of FIG. 6 correspond to a drive transistor 361A, an emission control transistor 362A, and a write transistor 363A of the first subpixel 6302A in FIG. 7, respectively. A well potential is supplied to the semiconductor substrate via well contacts WC3.

The gate of the drive transistor is the largest among the transistors of each subpixel in plan view of the substrate in FIG. 7. The gate of the drive transistor and the gate of the drive transistor of the pixel drive circuit of the adjacent subpixel are arranged not to overlap in the first direction X. The gates of the drive transistors of the adjacent subpixels are arranged not to overlap in the first direction X, not only when the adjacent subpixels are within one pixel but also when they are in different pixels.

This allows the pixel drive circuits for driving the subpixels to be densely arranged in a small area. For the gates formed from polysilicon, a sufficient distance between the gates is ensured even if the area of the pixel drive circuits is small, as described in the first and second embodiments.

Thus, variations in characteristics caused by manufacturing processes, such as polysilicon processing variations of the gates, can be suppressed.

Furthermore, also in the row having adjacent subpixels and the row of subpixels adjacent in the second direction Y, the gates of the drive transistors may be disposed not to overlap in the first direction X between the adjacent different pixels. This configuration enables the pixel drive circuits to be arranged more densely within a small area. Since the gates of the drive transistors in multiple pixel rows do not overlap in the first direction X, the transistors may be disposed densely, enabling the pixel drive circuits to be arranged densely within a smaller area.

Thus, in the multiple subpixels arranged in two-dimensional pattern, the gates of the drive transistors are arranged not to overlap in the first direction X in plan view of the substrate main surface (arranged in a staggered pattern). This enables the pixel drive circuits of the multiple subpixels to be arranged densely, thereby achieving the high definition and size-reduction of the light-emitting apparatus.

In the pixel array section 103 of this embodiment, adjacent subpixels in which the gates of the adjacent drive transistors are arranged so as not to overlap in the first direction X may be disposed in at least two adjacent rows. This allows achieving the above effects. All the pixels 101 arranged in the pixel array section 103 satisfy this configuration as it enables the densest arrangement of multiple pixel circuits. However, the effects of this embodiment can still be achieved even if only some pixels adopt this configuration. Accordingly, for example, the pixel array section 103 may include subpixels arranged at positions where the gates of the adjacent drive transistors overlap in the first direction.

The configuration will be described more specifically. For example, in the first pixel 360, the drive transistor 361A of the first subpixel 6302A includes a gate 365A, and the drive transistor 361B of the second subpixel 6302B includes a gate 365B. The drive transistor 361C of the third subpixel 6302C disposed between the first subpixel 6302A and the second subpixel 6302B includes a gate 365C.

In this case, the gate 365A of the drive transistor 361A of the first subpixel 6302A and the gate 365C of the drive transistor 361C of the adjacent third subpixel 6302C are arranged at positions that do not overlap in the first direction X. The gate 365C of the drive transistor 361C of the third subpixel 6302C and the gate 365B of the drive transistor 361B of the adjacent second subpixel 6302B are arranged at positions that do not overlap in the first direction X.

In the second pixel 370 adjacent to the first pixel 360, a second subpixel 7302B adjacent to the first subpixel 6302A includes a drive transistor 371B, and the drive transistor 371B includes a gate 375B. In this case, the gate 365A of the drive transistor 361A of the first subpixel 6302A of the first pixel 360 and the gate 375B of the drive transistor 371B of the second subpixel 7302B of the adjacent second pixel 370 are arranged at positions that do no overlap in the first direction X. The other adjacent subpixels may have the same configuration, though the description is omitted here.

The gate 365A of the drive transistor 361A is larger than the gate of the write transistor 363A in plan view of the main surface of the substrate. The gate 365A of the drive transistor 361A is larger than the gate of the emission control transistor 362A. The drive transistors and the write transistors constituting the pixel drive circuits of the other subpixels have the same configuration relationship.

The directions from the sources to the drains of the drive transistors of the first pixel 360 to the fourth pixel 390 shown in FIG. 7 are the same direction. For example, the direction from the sources to the drains of the drive transistors of the first pixel 360 and the direction from the sources to the drains of the drive transistors of the second pixel 370 are the same direction. Here, the term “same direction” refers to a substantially identical direction, including cases where there may be slight deviations due to manufacturing errors or the like.

Specifically, the direction from the source 367A to the drain 368A of the drive transistor 361A and the direction from the source 367B to the drain 368B of the drive transistor 361B are the same. Similarly, the direction from the source 367A to the drain 368A of the drive transistor 361A and the direction from the source 367C to the drain 368C of the drive transistor 361C are the same. The direction from the source 367A to the drain 368A of the drive transistor 361A and the direction from the source 377C to the drain 378C of the drive transistor 371C are the same. The other adjacent subpixels may have the same configuration, though the description is omitted here.

Since the drive transistors of different subpixels are arranged so that the directions from the sources to the drains are the same, manufacturing variations are less likely to cause characteristic variations. Thus, this embodiment provides a configuration in which the transistors of the pixel drive circuits are arranged most densely, and manufacturing variations are less likely to result in characteristic variations.

At least one of the width and length of the gate of the drive transistor 301 of one of the three subpixels of one pixel in FIG. 7 may be larger than at least one of the width and length of the gates of the drive transistors of the other two subpixels.

In FIG. 7, for example, the subpixel 6302C is a subpixel that emits green light, and the subpixel 6302A and the subpixel 6302B are subpixels that emit red or blue light. In the pixel 360, the width and length of the gate 365C of the drive transistor 361C are larger than the widths and lengths of the respective gates 365A and 365B of the drive transistors 361A and 361B of the other subpixels 6302A and 6302B.

This allows reducing the luminous variations of the light-emitting elements driven by the drive transistor 361C, thereby minimizing the luminance variations in the green subpixel, which has the greatest impact. This provides the effect of suppressing the luminance variation characteristics of the light-emitting apparatus. In contrast, the respective gates 365A and 365B of the drive transistors 361A and 361B of the subpixels 6202A and 6202B that emit blue or red light are smaller than the gate 365C of the drive transistor 361C, thereby preventing the pixel 360 from increasing in size.

However, in this embodiment, it is not necessary to dispose a pixel drive circuit having a drive transistor with the largest gate for the green light source. The pixel drive circuit may instead be disposed for a red light source or a blue light source. Alternatively, the widths and lengths of the gates of the drive transistors of the three subpixels may be all the same.

Even if the gate of the drive transistor differs in size between the subpixels, ensuring that the width-to-length ratios of the gates are equal allows the current-voltage characteristics of the transistors to be similar. This may reduce emission variations, etc. caused by the characteristic variations of the transistors of the subpixels.

Referring to FIG. 7, for example, in the first pixel 360, the write transistor 363A of the first subpixel 6302A and the write transistor 363C of the adjacent third subpixel 6302C are arranged so as to overlap at least partly in the first direction X.

For example, the write transistor 363A of the first subpixel 6302A of the first pixel 360 and the write transistor 373B of the second subpixel 7302B of the adjacent second pixel 370 may be arranged so as to overlap at least partly in the first direction X.

These write transistors are operated with the same scanning line 106b. Thus, by arranging at least part of the gates so as to overlap in the first direction X, the integration efficiency is enhanced, and the scanning line 106b can be arranged more easily in minimal area with low resistance.

Similarly, for example, in the pixel 360, the emission control transistor 362A of the first subpixel 6302A and the emission control transistor 362C of the adjacent third subpixel 6302C are arranged so as to overlap at least partly in the first direction X.

For example, the emission control transistor 362A of the first subpixel 6302A of the first pixel 360 and the emission control transistor 372B of the second subpixel 7302B of the adjacent second pixel 370 may be arranged so as to overlap at least partly in the first direction X.

These emission control transistors are operated with the same scanning line 106a. Thus, by arranging at least part of the gates so as to overlap in the first direction X, the integration efficiency is enhanced, and the scanning line 106b can be arranged more easily in minimal area with low resistance.

Here, the description has been made using the first subpixel 6302A and the third subpixel 6302C of the first pixel 360 and the second subpixel 7302B of the second pixel 370 as an example, this is illustrative only.

In the other adjacent subpixels, the same configuration allows the pixel drive circuits to be arranged within a smaller area and the scanning lines to be arranged more easily in minimum area with low resistance.

### Fourth Embodiment

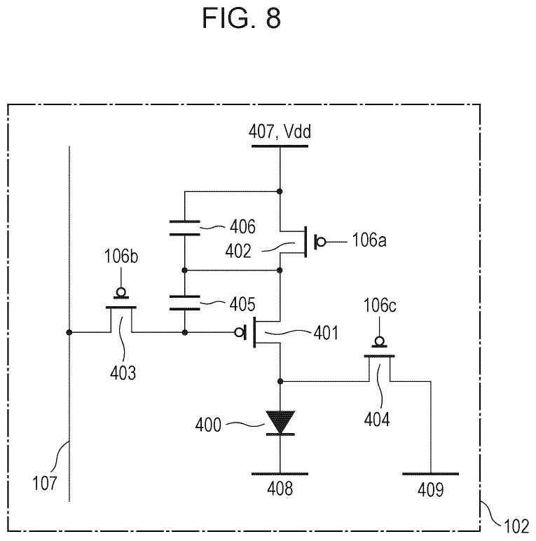

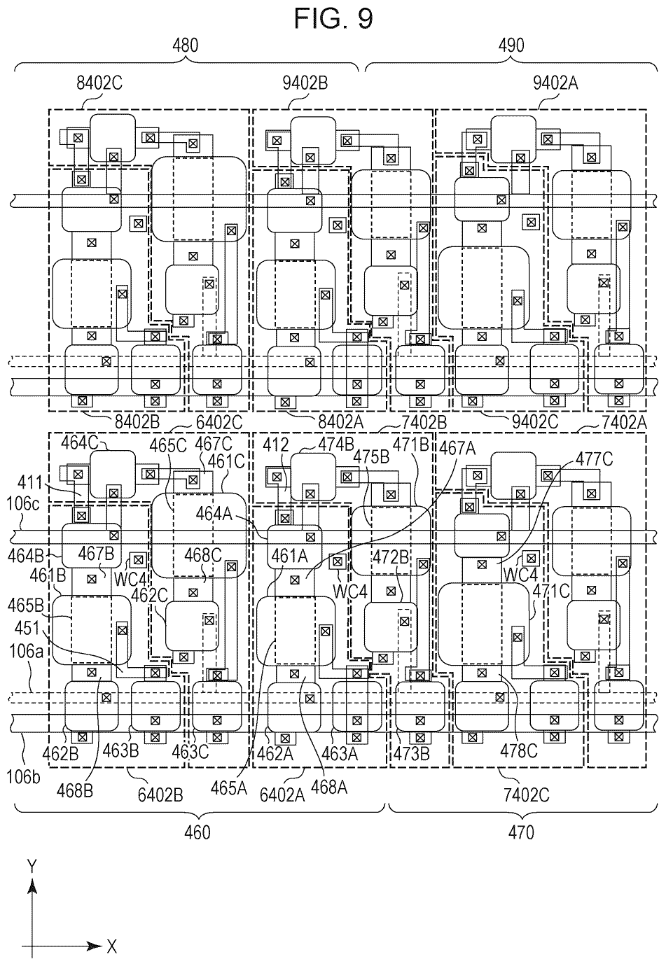

Referring to FIGS. 8 and 9, a light-emitting apparatus according to a fourth embodiment of the disclosure will be described. The same configurations, properties, materials, functions, and effects as those of the first to third embodiments will be omitted as appropriate.

FIG. 8 is a circuit diagram of a subpixel 102 of this embodiment. The subpixel 102 includes four transistors—a light-emitting element 400, a drive transistor 401, an emission control transistor 402, a write transistor 403, and a reset transistor 404. The subpixel 102 includes two capacitive element 405 and 406 (second capacitive elements). The four transistors may be, for example, MOSFETs.

Control signals are input to the gates of the emission control transistor 402, the write transistor 403, and the reset transistor 404 through three scanning lines 106a, 106b, and 106c. The signal line 107 connects to the source of the write transistor 403. When the write transistor 403 switches to ON state, the voltage on the signal line 107 is input to the gate of the drive transistor 401. The current that flows between the source and the drain of the drive transistor 401 depends on the signal voltage, thereby controlling the emission luminance of the light-emitting element 400.

The drain of the drive transistor 401 connects to the anode of the light-emitting element 400 and the source of the reset transistor 404. When the reset transistor 404 is in ON state, no current flows through the light-emitting element 400, and it does not emit light. The potential of the power supply line 407 may be higher than the potential of the power supply line 408. For example, the potential of the power supply line 407 may be 5 V, the potential of the power supply line 408 may be 0 V, and the potential of the power supply line 409 may be −2 V. These potentials are set based on the photoelectric conversion characteristics of the light-emitting element 400. The power supply line 408 and the power supply line 409 may be set to the same potential, for example, −2 V.

The capacitive elements 405 and 406 may have a metal film-insulator film-metal film configuration or a polysilicon-silicon oxide film-silicon configuration. The subpixel 102 shown in FIG. 8 includes the capacitive element 406; however, the subpixel 102 in this embodiment does not have to include the capacitive element 406.

The subpixels of this embodiment each include the reset transistor 404, in addition to the elements of the subpixels of the third embodiment. For this reason, the description will be made using the configuration of the third embodiment as appropriate for the sake of ease. In the reset transistor 404, one of the source and the drain connects to the light-emitting element 400 and the emission control transistor 462, and the other connects to the power supply line 409 (a second power supply line).

FIG. 9 is a plan view of the transistors, which are components of the pixel drive circuit of the subpixel 102 according to this embodiment. In the subpixel 102 of FIG. 8, the drain of the emission control transistor 402 and the source of the drive transistor 401 have the same potential and share the same node. Likewise, the drain of the drive transistor 401 and the source of the reset transistor 404 share the same node. The drain of the write transistor 403 and the gate of the drive transistor 401 are connected by a wiring line 451 (FIG. 9).

FIG. 9 is a plan view of the main surface of the substrate, illustrating part of the electrodes and the wiring lines illustrated in FIG. 8, and contact plugs. The pixel circuit of the subpixel 102 shown in FIG. 8 includes a wiring layer on the main surface of the substrate and includes a wiring pattern (including, for example, metal and polysilicon) and contact plugs.

FIG. 9 is a plan view of the transistors of the pixel drive circuits in this embodiment. A first pixel 460, a second pixel 470, a third pixel 480, and a fourth pixel 490 correspond to the first pixel 360, the second pixel 370, the third pixel 380, and the fourth pixel 390 of the third embodiment, respectively.

For example, the multiple pixels include the first pixel 460 and the second pixel 470 adjacent to each other in the first direction X and the third pixel 480 and the fourth pixel 490 adjacent to each other in the first direction X. The first pixel 460 and the second pixel 470 are respectively adjacent to the third pixel 480 and the fourth pixel 490 in the second direction Y intersecting the first direction X. The first direction X and the second direction Y may intersect at an angle less than 90° rather than at right angles.

The first pixel 460 includes a first subpixel 6402A, a second subpixel 6402B, and a third subpixel 6402C. The second pixel 470, the third pixel 480, and the fourth pixel 490 also each include a first subpixel, a second subpixel, and a third subpixel. For the subpixels within these pixels, descriptions of the similar parts will be omitted as appropriate.

The following description will be made mainly using the first pixel 460. The other pixels also have the same configurations, materials, properties, functions, effects, etc. as those of the first pixel 460, unless otherwise specified.

A drive transistor 461A in FIG. 9 corresponds to the drive transistor 361A in FIG. 7. A write transistor 463A in FIG. 9 corresponds to the write transistor 363A in FIG. 7. For example, the drive transistor 401, the emission control transistor 402, and the write transistor 403 of the pixel drive circuit of FIG. 8 correspond to a drive transistor 461A, an emission control transistor 462A, and a write transistor 463A of the first subpixel 6402A in FIG. 9, respectively. A well potential is supplied to the semiconductor substrate via well contacts WC4.

The gate of the drive transistor is the largest among the transistors of each subpixel in plan view of the substrate in FIG. 9. The gate of the drive transistor and the gate of the drive transistor of the pixel drive circuit of the adjacent subpixel are arranged not to overlap in the first direction X. The gates of the drive transistors of the adjacent subpixels are arranged not to overlap in the first direction X, not only when the adjacent subpixels are within one pixel but also when they are in different pixels.

This allows the pixel drive circuits for driving the subpixels to be densely arranged in a small area. For the gates formed from polysilicon, a sufficient distance between the gates is ensured even if the area of the pixel drive circuits is small, as described in the first to third embodiments.

Thus, variations in characteristics caused by manufacturing processes, such as polysilicon processing variations of the gates, can be suppressed.

Furthermore, also in the row having adjacent subpixels and the row of subpixels adjacent in the second direction Y, the gates of the drive transistors may be disposed not to overlap in the first direction X between the adjacent different pixels. This configuration enables the pixel drive circuits to be arranged more densely within a small area. Since the gates of the drive transistors in multiple pixel rows do not overlap in the first direction X, the transistors may be disposed densely, enabling the pixel drive circuits to be arranged densely within a smaller area.

Thus, in the multiple subpixels arranged in two-dimensional pattern, the gates of the drive transistors are arranged not to overlap in the first direction X in plan view of the substrate main surface (arranged in a staggered pattern). This enables the pixel drive circuits of the multiple subpixels to be arranged densely, thereby achieving the high definition and size-reduction of the light-emitting apparatus.

In the pixel array section 103 of this embodiment, adjacent subpixels in which the gates of the adjacent drive transistors are arranged so as not to overlap in the first direction X may be disposed in at least two adjacent rows. This allows achieving the above effects. All the pixels 101 arranged in the pixel array section 103 satisfy this configuration as it enables the densest arrangement of multiple pixel circuits. However, the effects of this embodiment can still be achieved even if only some pixels adopt this configuration. Accordingly, for example, the pixel array section 103 may include subpixels arranged at positions where the gates of the adjacent drive transistors overlap in the first direction.

The configuration will be described more specifically. For example, in the first pixel 460, the drive transistor 461A of the first subpixel 6402A includes a gate 465A, and the drive transistor 461B of the second subpixel 6402B includes a gate 465B. The drive transistor 461C of the third subpixel 6402C disposed between the first subpixel 6402A and the second subpixel 6402B includes a gate 465C.

In this case, the gate 465A of the drive transistor 461A of the first subpixel 6402A and the gate 465C of the drive transistor 461C of the adjacent third subpixel 6402C are arranged at positions that do not overlap in the first direction X. The gate 465C of the drive transistor 461C of the third subpixel 6402C and the gate 465B of the drive transistor 461B of the adjacent second subpixel 6402B are arranged at positions that do not overlap in the first direction X.

In the second pixel 470 adjacent to the first pixel 460, a second subpixel 7402B adjacent to the first subpixel 6402A includes a drive transistor 471B, and the drive transistor 471B includes a gate 475B. In this case, the gate 465A of the drive transistor 461A of the first subpixel 6402A of the first pixel 460 and the gate 475B of the drive transistor 471B of the second subpixel 7202B of the adjacent second pixel 470 are arranged at positions that do no overlap in the first direction X. The other adjacent subpixels may have the same configuration, though the description is omitted here.

The gate 465A of the drive transistor 461A is larger than the gate of the write transistor 463A in plan view of the main surface of the substrate. The gate 465A of the drive transistor 461A is larger than the gate of the emission control transistor 462A and the gate of the reset transistor 464A. The drive transistors, the write transistors, the emission control transistors, and the reset transistors constituting the pixel drive circuits of the other subpixels have the same configuration relationship.

The directions from the sources to the drains of the drive transistors of the first pixel 460 to the fourth pixel 490 shown in FIG. 9 are the same direction. For example, the direction from the sources to the drains of the drive transistors of the first pixel 460 and the direction from the sources to the drains of the drive transistors of the second pixel 470 are the same direction. Here, the term “same direction” refers to a substantially identical direction, including cases where there may be slight deviations due to manufacturing errors or the like.

Specifically, the direction from the source 467A to the drain 468A of the drive transistor 461A and the direction from the source 467B to the drain 468B of the drive transistor 461B are the same. Similarly, the direction from the source 467A to the drain 468A of the drive transistor 461A and the direction from the source 467C to the drain 468C of the drive transistor 461C are the same. The direction from the source 467A to the drain 468A of the drive transistor 461A and the direction from the source 477C to the drain 478C of the drive transistor 471C are the same. The other adjacent subpixels may have the same configuration, though the description is omitted here.

Since the drive transistors of different subpixels are arranged so that the directions from the sources to the drains are the same, manufacturing variations are less likely to cause characteristic variations. Thus, this embodiment provides a configuration in which the transistors of the pixel drive circuits are arranged most densely, and manufacturing variations are less likely to result in characteristic variations.

At least one of the width and length of the gate of the drive transistor 401 of one of the three subpixels of one subpixel in FIG. 9 may be larger than at least one of the width and length of the gates of the drive transistors of the other two subpixels.

In FIG. 9, for example, the subpixel 6402C is a subpixel that emits green light, and the subpixel 6402A and the subpixel 6402B are subpixels that emit red or blue light. In the pixel 460, the width and length of the gate 465C of the drive transistor 461C are larger than the widths and lengths of the respective gates 465A and 465B of the drive transistors 461A and 461B of the other subpixels 6402A and 6402B.

This allows reducing the luminous variations of the light-emitting elements driven by the drive transistor 461C, thereby minimizing the luminance variations in the green subpixel, which has the greatest impact. This provides the effect of suppressing the luminance variation characteristics of the light-emitting apparatus. In contrast, the respective gates 465A and 465B of the drive transistors 461A and 461B of the subpixels 6402A and 6402B that emit blue or red light are smaller than the gate 465C of the drive transistor 461C, thereby preventing the pixel 460 from increasing in size.

However, in this embodiment, it is not necessary to dispose a pixel drive circuit having a drive transistor with the largest gate for the green light source. The pixel drive circuit may instead be disposed for a red light source or a blue light source. Alternatively, the widths and lengths of the gates of the drive transistors of the three subpixels may be all the same.

Even if the gate of the drive transistor differs in size between the subpixels, ensuring that the width-to-length ratios of the gates are equal allows the current-voltage characteristics of the transistors to be similar. This may reduce emission variations, etc. caused by the characteristic variations of the transistors of the subpixels.

Referring to FIG. 9, for example, in the first pixel 460, the write transistor 463A of the first subpixel 6402A and the write transistor 463C of the adjacent third subpixel 6402C are arranged so as to overlap at least partly in the first direction X.

For example, the write transistor 463A of the first subpixel 6402A of the first pixel 460 and the write transistor 473B of the second subpixel 7402B of the adjacent second pixel 470 may be arranged so as to overlap at least partly in the first direction X.

These write transistors are operated with the same scanning line 106b. Thus, by arranging at least part of the gates so as to overlap in the first direction X, the integration efficiency is enhanced, and the scanning line 106b can be arranged more easily in minimal area with low resistance.

Similarly, for example, in the pixel 460, the emission control transistor 462A of the first subpixel 6402A and the emission control transistor 462C of the adjacent third subpixel 6402C are arranged so as to overlap at least partly in the first direction X.

For example, the emission control transistor 462A of the first subpixel 6402A of the first pixel 460 and the emission control transistor 472B of the second subpixel 7402B of the adjacent second pixel 470 may be arranged so as to overlap at least partly in the first direction X.

These emission control transistors are operated with the same scanning line 106a. Thus, by arranging at least part of the gates so as to overlap in the first direction X, the integration efficiency is enhanced, and the scanning line 106b can be arranged more easily in minimal area with low resistance.

Here, the description has been made using the first subpixel 6402A and the third subpixel 6402C of the first pixel 460 and the second subpixel 7402B of the second pixel 470 as an example, this is illustrative only.

In the other adjacent subpixels, the same configuration allows the pixel drive circuits to be arranged within a smaller area and the scanning lines to be arranged more easily in minimum area with low resistance.

The emission control transistor 402, the write transistor 403, and the reset transistor 404 of this embodiment have the function of a switch in each pixel drive circuit. In contrast, the drive transistor 401 is used to control the current that flows through the light-emitting element 400. In other words, requirements for manufacturing variations and characteristic variations of the three transistors other than the drive transistor 401 are not as stringent than those for the drive transistor.

Accordingly, for example, the reset transistor 464 may be arranged so that the directions from the source to the drain intersect at right angles between the adjacent subpixels 102, as shown in FIG. 9. This is for the purpose of arranging the reset transistor 464 within a limited area. The drains of the reset transistors 464 of the adjacent subpixels may be directly electrically connected by a wiring line or the active regions of the transistors as shown in FIG. 9. This allows providing a display apparatus including minute pixels constituted of densely arranged transistors.

To provide this configuration, this embodiment is configured such that the drains of the reset transistors 464 are directly connected with a wiring line or the active regions of the transistors in two subpixels in the pixel 460. In contrast, in the two subpixels adjacent to the subpixel, the drains of the reset transistors 464 are directly connected by the wiring line or the active regions of the transistors between the pixel 460 and the pixel 470.

In other words, the configuration in which the reset transistors of the two subpixels in one pixel are directly connected by a wiring line or the active regions and the configuration in which the two reset transistors of the different adjacent pixels are connected by a wiring line or active regions are alternately arranged in the first direction X.

For example, in FIG. 9, the reset transistor 464B of the second subpixel 6402B of the first pixel 460 and the reset transistor 464C of the first pixel 460 of the third subpixel 6402C are directly connected by a wiring line 411. The reset transistor 464A of the first subpixel 6402A of the first pixel 460 and the reset transistor 474B of the second subpixel 7402B of the second pixel 470 are directly connected by a wiring line 412. In FIG. 9, the gates of the reset transistors of the adjacent two subpixels are arranged so as to overlap at least partly in the second direction Y.

This configuration allows the transistors of the pixel drive circuits of the subpixels 102 to be arranged within a smaller area, that is, densely, in the first direction X and the second direction Y. Thus, high definition and size reduction of the display apparatus can be achieved.

In FIG. 9, the gate 465A of the drive transistor 461A of the first subpixel 6402A is arranged between the gate of the emission control transistor 462C of the third subpixel 6402C and the gate of the emission control transistor 472B of the second subpixel 7402B of the second pixel 470 in the first direction X. This configuration allows the transistors of the pixel drive circuits of the subpixels 102 to be arranged within a smaller area, that is, densely. Thus, high definition and size reduction of the display apparatus can be achieved.

The gate of the emission control transistor 462A of the first subpixel 6402A is arranged between the gate of the write transistor 463C of the third subpixel 6402C and the gate of the write transistor 463A of the first subpixel 6402A in the first direction X. This configuration allows the transistors of the pixel drive circuits of the subpixels 102 to be arranged within a smaller area, that is, densely. Thus, high definition and size reduction of the display apparatus can be achieved.

In the first subpixel 6402A of the first pixel 460, the gate 465A of the drive transistor 461A is arranged between the gate of the emission control transistor 462A and the reset transistor 464A in the second direction Y. This configuration allows the transistors of the pixel drive circuits of the subpixels 102 to be arranged within a smaller area, that is, densely. Thus, high definition and size reduction of the display apparatus can be achieved.

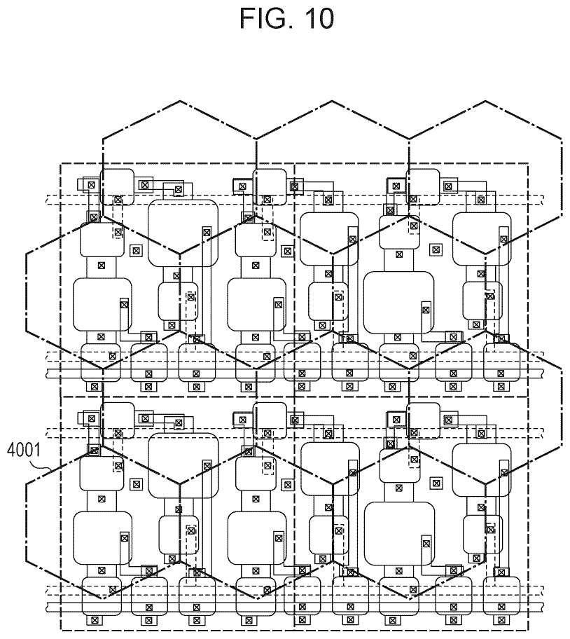

FIG. 10 illustrates an example of the outer edge 4001 of the subpixel 102 in the upper layer of the pixel circuit, including light-emitting elements etc., using a dashed-dotted line in plan view of part of the display apparatus shown in FIG. 9. The pixel drive circuits are arranged substantially in rows and columns in the first direction and the second direction. The upper layer may have a honeycomb structure such that the approximate hexagonal subpixels 102 are minute. This arrangement ensures a large light-emitting area, thereby improving the luminance of the display apparatus.

Although this embodiment shows an example in which the outer edge 2001 of each subpixel 102 in the upper layer is approximately hexagonal, and the subpixels 102 are arranged like a honeycomb structure, the shape of the subpixel 102 of this embodiment is illustrative only. The subpixels 102 may have a shape and arrangement corresponding to the shape and arrangement of the pixel drive circuits, including a stripe layout and a PenTile layout.

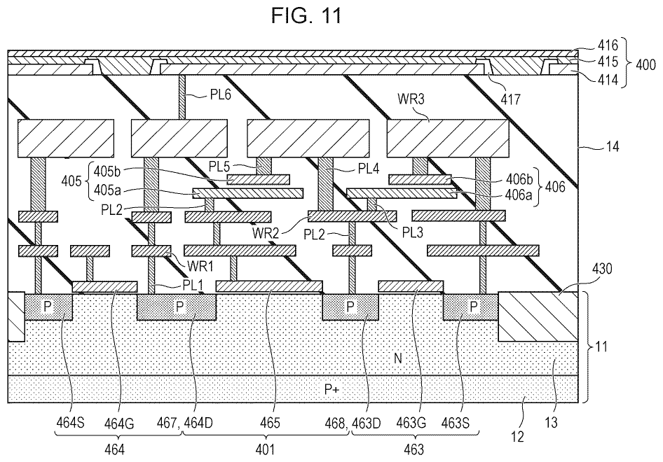

Next, a cross section of an example of part of the light-emitting apparatus of this embodiment will be described with reference to FIG. 11. This is an example of the light-emitting apparatus of this embodiment; however, any of the light-emitting apparatuses described in the first to third embodiments may have a similar configuration.

The light-emitting apparatus includes a substrate 11, an insulating layer 14, and a light-emitting element 400. The insulating layer 14 is positioned on the substrate 11. The light-emitting element 400 is positioned on the insulating layer 14. In other words, the insulating layer 14 is positioned between the substrate 11 and the light-emitting element 400.

The substrate 11 includes a main surface (in FIG. 11, the upper surface) on which the drive transistors 401, the write-control transistors 403, and the emission control transistors 402 are formed. The substrate 14 may, for example, be formed of a P-type semiconductor. An N-type well region 13 is formed on the main surface side of the substrate 11 (that is, the upper part of the substrate 11). The portion of the substrate 11 other than the well region 13 is a P-type semiconductor region 12.

The substrate 11 includes multiple impurity regions serving as the source regions or the drain regions of the transistors in the well region 13. The conductivity type of the impurity regions may, for example, be P-type.

Conductive layers 465, 463G, and 464G are arranged within the main surface (upper surface) of the substrate 11. The conductive layer 463G functions as the gate of the emission control transistor 463. One of the P-type impurity regions functions as the source 463S of the emission control transistor 463, and another of the P-type impurity regions functions as the drain 463D. The conductive layer 465 functions as the gate of the drive transistor 461. The impurity region that functions as the drain 463D of the emission control transistor 463 also functions as the source 468 of the drive transistor 401. Another of the P-type impurity regions functions as the drain 467 of the drive transistor 401.

The conductive layer 464G functions as the gate of the reset transistor 464. The impurity region that functions as the source 468 of the drive transistor 401 also functions as the drain 464D of the reset transistor 464. Another of the P-type impurity regions functions as the source 464S of the reset transistor 464.

The substrate 11 further includes element isolation portions 430 each formed between the adjacent pixels 101.

The element isolation portion 430 may use shallow trench isolation (STI), local oxidation of silicon (LOCOS) isolation, or N-type diffusion layer isolation.

The light-emitting element includes, a cathode 416, an organic light-emitting layer 415, and an anode 414. The cathode 416 is electrically connected to the power supply line 408. The anode 414 is electrically connected to the main terminal (in this case, the drain) of the drive transistor 401. The organic light-emitting layer 415 is positioned between the cathode 416 and the anode 414. A bank 417 is arranged at an end of the anode 414. The bank 417 prevents the current flowing between the anode 414 and the cathode 416 from leaking to the adjacent pixel 101.

The insulating layer 14 contains conductive patterns, the electrodes of capacitive elements, and plugs. One example of the insulating layer 14 is made of silicon oxide. Each of the conductive patterns may be a wiring layer. For example, the conductive patterns may include wiring lines WR1, WR2, and WR3, as shown in FIG. 11.

The capacitive element 405 includes electrodes 405a and 405b. The capacitive element 406 includes electrodes 406a and 406b. In the insulating layer 14, the electrodes 405a and 406a may be arranged on the same insulating layer, and the electrodes 405b and 406b may be arranged on the same insulating layer. The electrodes 405a and 405b face each other across the insulating layer. The electrodes 406a and 406b face each other across the insulating layer. Thus, a capacitive element with a metal-insulator-metal (MIM) structure is formed.

The multiple plugs may include, for example, plugs PL1, PL2, PL3, PL4, PL5, and PL6. The multiple plugs may have the same thickness or different thicknesses, or alternatively, some plugs may have the same thickness, and the other may have different thicknesses.

The plug PL1 may connect the wiring line WR1 and a terminal (one of the gate, source, and drain) of the transistor. The plug PL2 may connect the wiring lines WR1 and WR2 together. The lower electrode of the capacitive element (405 or 406) may be connected to the drive transistor 401 via the plug PL3, the wiring line WR2, the plug PL2, the wiring line WR1, and the plug PL1. The upper electrode of the capacitive element (405 or 406) may be connected to the wiring line WR3 via the plug PL5.

The wiring line WR3 may be connected to a transistor (in FIG. 11, one of the drive transistor, the current control transistor, and the reset transistor) via the plug PL4, the wiring line WR2, the plug PL2, the wiring line WR1, and the plug PL1. The anode 414 may be connected to the source 467 of the drive transistor 401 via the plug PL6, the wiring line WR3, the plug PL4, the wiring line WR2, the plug PL2, wiring line WR1, and the plug PL1.

The plugs may be formed in a separate process from the wiring lines or in the same process as the wiring lines arranged on the plugs. For example, the wiring line WR2 and the plug PL2 may be formed in the same process and may be made of the same material. The wiring line WR3 and the plug PL4 may be formed in the same process and may be made of the same material.

The wiring lines and the plugs may be formed of elementary metal such as copper, tungsten, aluminum, or titanium, or their alloy.

Thus, by using the semiconductor substrate as the substrate and using MOS transistors for the transistors of each pixel 101, the transistors can be arranged more densely compared to when thin-film transistors are used. Thus, since the light-emitting apparatus of this embodiment has a semiconductor substrate and MOS transistors, it is possible to achieve higher definition and greater miniaturization.

### Fifth Embodiment

Next, an example of an organic light-emitting element that can be used in the light-emitting apparatus according to one of the first to fourth embodiments will be described. The organic light-emitting element according to this embodiment includes a first electrode, a second electrode, and an organic compound layer disposed between these electrodes. One of the first electrode and the second electrode is an anode, and the other is a cathode. In the organic light-emitting element of this embodiment, the organic compound layer may be a single layer or a multilayer structure composed of multiple layers that includes a light-emitting layer. The organic compound layer, if it is a multilayer structure composed of multiple layers, may include, in addition to the light-emitting layer, a hole injection layer, a hole transport layer, an electron blocking layer, a hole and exciton blocking layer, an electron transport layer, an electron injection layer, and so on. The light-emitting layer may be a single layer or a multilayer structure composed of multiple layers. The light-emitting layer, if it is a multilayer structure, may include a charge generating layer between the light-emitting layers. The charge generating layer may be formed of a compound whose lowest unoccupied molecular orbital (LUMO) is lower than that of the hole transport layer. The LUMO of the charge generating layer may be lower than the HOMO of the hole transport layer. The molecular orbital energy of the organic compound layer may be the molecular orbital energy of an organic compound with the highest weight ratio in the organic compound layer.

In the organic light-emitting element of this embodiment, if the organic compound according to this embodiment is included in the light-emitting layer, the light-emitting layer may be composed of only the organic compound according to this embodiment or may be composed of an organometallic complex according to this embodiment and another compound. If the light-emitting layer is composed of the organometallic complex according to this embodiment and another compound, the organic compound according to this embodiment may be used as the host of the light-emitting layer or as a guest. The organic compound may be used as an assist material which can be included in the light-emitting layer. Here, the host is a compound with the highest mass ratio in the compounds constituting the light-emitting layer. The guest is a compound whose mass ratio is lower than that of the host in the compounds constituting the light-emitting layer and is responsible for the primary light emission. The assist material is a compound whose mass ratio is lower than that of the host in the compounds constituting the light-emitting layer and assists the light emission of the guest. The assist material is also referred to as a second host. The host material may also be referred to as a first compound, and the assist material may also be referred to as a second compound.

The organic compound according to this embodiment may be used together with a known low molecular or high molecular hole-injecting compound or hole-transporting compound, a host compound, a light-emitting compound, or an electron-injecting compound or an electron-transporting compound.

A hole-injection or -transporting material may be a material with higher hole mobility so as to facilitate hole injection from the anode and enable transportation of the injected holes to the light-emitting layer. Furthermore, a material with a high glass-transition temperature may be used to reduce the membranous deterioration such as crystallization in the organic light-emitting element.

The electron-transporting material may be freely selected from materials that can transport electrons injected from the cathode to the light-emitting layer in consideration of factors such as the balance with the hole mobility of the hole-transporting material. The electron-transporting material is suitably used also for the hole blocking layer.

The electron-injecting material may be freely selected from materials to which electrons are easily injected from the cathode in consideration of factors such as the balance with the hole injecting performance. The electron-injecting material may be used in combination with the electron-transporting material.

### Configuration of Organic Light-Emitting Element

The organic light-emitting element includes an insulating layer, a first electrode, an organic compound layer, and a second electrode on a substrate. A protective layer, color filters, microlenses and so on may be provided on the cathode.

If color filters are provided, a planarizing layer may be provided between the color filters and the protective layer. The planarizing layer may be made of an acrylate resin or the like. This also applies to a planarizing layer disposed between the color filters and the microlenses.

### Substrate

Example materials for the substrate include quartz, glass, silicon wafer, resin, and metal. Switching elements, such as transistors, and wiring lines may be provided on the substrate, on which an insulating layer may be provided. If a silicon wafer is used for the substrate, the active layers, the source regions, and the drain regions of the transistors are formed in the substrate. This allows the transistors to be arranged densely.

The insulating layer may be made of any material in which contact holes can be formed to allow wiring to the first electrode and which ensures insulation from unconnected wiring lines. Examples include resin, such as polyimide, silicon oxide, and silicon nitride.

### Electrode

A pair of electrodes may be used. The pair of electrodes may be an anode and a cathode.

When an electric field is impressed in the direction in which the organic light-emitting element emits light, the electrode with a higher potential serves as the anode, while the other electrode serves as the cathode. In other words, the electrode that supplies holes to the light-emitting layer serves as the anode, while the electrode that supplies electrons serves as the cathode.

The constituent material of the anode may be a material with a work function as large as possible. Examples include elementary metals, such as gold, platinum, silver, copper, nickel, palladium, cobalt, selenium, vanadium, and tungsten, mixtures that contains them, their alloys, and metal oxides, such as tin oxide, zinc oxide, indium oxide, indium tin oxide (ITO), and indium zinc oxide. Other examples include conductive polymers, such as polyaniline, polypyrrole, and polythiophene.

These electrode substances may be used alone or in combination of two or more kinds. The anode may be in one layer or a plurality of layers.

For a reflecting electrode, materials such as chromium, aluminum, silver, titanium, tungsten, molybdenum, their alloys, or laminated structures thereof may be used. A reflecting film that does not serve as an electrode may be made of the above materials. For a transparent electrode, examples of materials include, but are not limited to, transparent oxide conductive layers such as indium tin oxide (ITO) and indium zinc oxide.

The electrodes may be formed using a photolithography technique.

A material for the cathode may have a small work function. Examples include alkali metal such as lithium, alkali earth metal such as calcium, elementary metals such as aluminum, titanium, manganese, silver, lead, and chromium, and mixtures containing them. Other examples include alloys of these elementary metals, for example, magnesium-silver, aluminum-lithium, aluminum-magnesium, silver-copper, and zinc-silver alloys. Metal oxides such as indium tin oxide (ITO) may be used.

These electrode materials may be used alone or in combination of two or more kinds. The cathode may have a one-layer structure or a multiple-layer structure. Among them, silver may be used, or a silver alloy may be used to reduce aggregation of silver. Any alloy ratio that reduces silver aggregation may be employed. For example, the ratio of silver to another metal may be 1:1 or 3:1.

The cathode may be made of, but is not limited to, an oxide conductive layer such as ITO to serve as a top emission element or a reflecting electrode such as aluminum (Al) to serve as a bottom emission element. The cathode may be formed by, but is not limited to, direct-current sputtering or alternate-current sputtering to provide good film coverage, thereby easily decreasing the resistance.

### Pixel Isolating Layer

A pixel isolating layer is formed of a silicon nitride (SiN) film, a silicon oxynitride (SiON) film, or a silicon oxide (SiO) film using a chemical vapor deposition (CVD) method.

To increase the in-plane resistance of the organic compound layer, the thickness of the organic compound layer, in particular, the hole transport layer, may be small on the side wall of the pixel isolating layer. Specifically, by increasing the taper angle of the side wall or the thickness of the pixel isolating layer to enhance shadowing during vapor deposition, the thickness of the film on the side wall can be small.

The taper angle of the side wall or the thickness of the pixel isolating layer may be adjusted so that no gap is formed in the protective layer on the pixel isolating layer. Since no gaps are formed in the protective layer, the occurrence of defects in the protective layer is reduced. Since the occurrence of defects in the protective layer is reduced, the occurrence of reliability issues, such as dark spots and defective continuity in the second electrode, is reduced.

By adjusting the taper angle of the side wall of the pixel isolating layer, charge leakage to the adjacent pixels is effectively suppressed. For example, it has been found that a taper angle ranging from 60 degrees to 90 degrees may sufficiently reduce charge leakage. In one embodiment, the thickness of the pixel isolating layer is from 10 nm to 150 nm. Pixel electrodes without the pixel isolating layer may provide similar effects. However, in this case, the thickness of the pixel electrodes is half that of the organic layer or less, or the ends of the pixel electrode are forward tapered at an angle of less than 60°, because these measures help reduce short circuits in the organic light-emitting element.

### Organic Compound Layer

The organic compound layer may be in a single layer or in multiple layers. In the case of multiple layers, the layers may be referred to as a hole injection layer, a hole transport layer, an electron blocking layer, a light-emitting layer, a hole blocking layer, an electron transport layer, or an electron injection layer according to their functions. The organic compound layer is mainly composed of an organic compound but may contain inorganic atoms or an inorganic compound, such as copper, lithium, magnesium, aluminum, iridium, platinum, molybdenum, or zinc. The organic compound layer may be disposed between the first electrode and the second electrode and may be in contact with the first electrode and the second electrode.

With multiple light-emitting layers, a charge generating section may be provided between a first light-emitting layer and a second light-emitting layer. The charge generating section may include an organic compound with a lowest unoccupied molecular orbital (LUMO) energy of −5.0 eV or less. This also applies to a charge generating portion disposed between the second light-emitting layer and the third light-emitting layer.

### Protective Layer

A protective layer may be provided on the second electrode. For example, bonding glass with absorbent to the second electrode reduces immersion of water or the like into the organic compound layer, thereby reducing display defect. In another embodiment, a passivation film such as silicon nitride may be provided on the cathode to reduce immersion of water or the like into the organic compound layer. For example, the cathode is formed and is then transported to another chamber under vacuum, where a silicon nitride film with a thickness of 2 μm is formed by the CVD method to serve as a protective layer. After the film deposition by the CVD method, a protective layer may be formed using atomic layer deposition (ALD). Examples of a material for forming the film by the ALD method include, but are not limited to, silicon nitride, silicon oxide, and aluminum oxide. Silicon nitride may be deposited by the CVD method on the film formed by the ALD method. The film formed by the ALD method may have a thickness smaller than that of the film formed by the CVD method, specifically, 50% or less or 10% or less.

### Color Filter

Color filters may be provided on the protective layer. For example, color filters formed in consideration of the size of the organic light-emitting elements may be provided on another substrate, and it may be bonded to a substrate provided with the organic light-emitting elements, or alternatively, color filters may be patterned on the protective layer using a photolithography technique. The color filters may be composed of a polymeric material.

### Planarizing Layer

A planarizing layer may be provided between the color filters and the protective layer. The planarizing layer is provided to reduce the unevenness of the layer thereunder. The layer is sometimes referred to as “material resin layer” without limiting the purpose. The planarizing layer may be composed of an organic compound and may be either low molecular or high molecular.

The planarizing layer may be provided on and under the color filters. Their materials may be the same or may differ. Specific examples include a polyvinyl carbazole resin, a polycarbonate resin, a polyester resin, an acrylonitrile-butadiene-styrene (ABS) resin, an acrylate resin, a polyimide resin, a phenol resin, an epoxy resin, a silicon resin, and a urea resin.

### Microlens

The light-emitting apparatus may include an optical member such as a microlens on the light emission side. The microlens may be formed of an acrylate resin or an epoxy resin. The microlens may be designed to increase the amount of light taken from the light-emitting apparatus and control its direction. The microlens may have a hemispherical shape. With the hemispherical shape, of tangent lines in contact with the hemisphere, a contact point between a tangent line parallel to the insulating layer and the hemisphere is the apex of the microlens. The apex of the microlens may be determined in any cross-sectional view. In other word, of the tangent lines in contact with the hemisphere of the microlens in cross-sectional view, a contact point between the tangent line parallel to the insulating layer and the hemisphere is the apex of the microlens.

The middle point of the microlens may also be defined. Assuming a line segment from an end to another end of a circular arc in a cross section of the microlens, the middle point of the line segment may be referred to as the middle point of the microlens. The cross section for determining the apex and the middle point may be a cross section perpendicular to the insulating layer.

The microlens includes a first surface curving out and a second surface opposite to the first surface. The second surface may be positioned closer to the functional layer than the first surface. To achieve such a configuration, the microlenses are to be formed on the light-emitting apparatus. In cases where the functional layer is an organic layer, high-temperature processes during manufacturing processing may be avoided. For the configuration in which the second surface is positioned closer to the functional layer than the first surface, in one embodiment, the glass transition temperature of the organic compound that constitutes the organic layer is 100° C. or more, and in another embodiment, the organic layer is 130° C. or more.

### Counter Substrate

A counter substrate may be provided on the planarizing layer. The counter substrate is disposed at a position opposite to the above-described substrate and is therefore referred to as “counter substrate”. The material for the counter substrate may be the same as that of the above-described substrate. If the above-described substrate is a first substrate, the counter substrate may be a second substrate.

### Organic Layer

Organic compound layers (a hole injection layer, a hole transport layer, an electron blocking layer, a light-emitting layer, a hole blocking layer, an electron transport layer, an electron injection layer, and so on) constituting the organic light-emitting element according to an embodiment are formed by the following method.

The organic compound layers constituting the organic light-emitting element according to an embodiment can be formed by using a dry process, such as vacuum deposition, ionized deposition, sputtering, or plasma sputtering. In place of the dry process, a wet process of forming layers by applying a solution using an appropriate solvent by using a known coating method (for example, spin coating, dipping, a cast method, a Langmuir-Blodgett [LB] method, or an ink-jet method) may be used).

Layers formed using the vacuum deposition method or the solution coating method are unlikely to be crystalized and have high temporal stability. The coating method allows film deposition in combination with an appropriate binder resin.

Examples of the binder resin includes, but are not limited to, a polyvinyl carbazole resin, a polycarbonate resin, a polyester resin, an ABS resin, an acrylate resin, a polyimide resin, a phenol resin, an epoxy resin, a silicon resin, and a urea resin.

These binder resins may be used alone or in combination of two or more kinds as a homopolymer or a copolymer. A known additive, such as plasticizer, oxidation inhibitor, or ultraviolet absorbent, may be used as needed.

### Pixel Circuit

The light-emitting apparatus may include a pixel circuit connected to the light-emitting element. The pixel circuit may be of an active matrix type that controls a first light-emitting element and a second light-emitting element independently. The active matrix circuit may employ either voltage programing or current programing. The drive circuit includes a pixel circuit for each pixel. The pixel circuit may include a light-emitting element, a transistor that controls the emission luminance of the light-emitting element, a transistor that controls the emission timing, a capacitor that holds the gate voltage of the transistor that controls the emission timing, and a transistor for connecting to a ground GND without passing through the light-emitting element.

The light-emitting apparatus includes a display area and a peripheral area disposed around the display area. The display area includes a pixel circuit. The peripheral area includes a display control circuit. The mobility of transistors constituting the pixel circuit may be lower than the mobility of transistors constituting the display control circuit.

The inclination of the current-voltage characteristics of the transistors constituting the pixel circuit may be smaller than the inclination of the current-voltage characteristics of the transistors constituting the display control circuit. The inclination of the current-voltage characteristics may be measured using so-called Vg-Ig characteristics.

The transistors constituting the pixel circuit are connected to light-emitting elements including the first light-emitting element.

### Pixel

The light-emitting apparatus includes multiple pixels as has been described in the above embodiments. The pixels each include subpixels that emit light of a color different from the other colors. The subpixels may individually emit red, green, and blue (RGB) lights.

The pixels emit light from an area called a pixel aperture.

By using the configuration of the light-emitting apparatus according to at least one of the first to fourth embodiments, the distance between the subpixels (between the centers of adjacent subpixels) can be set to, for example, 6.4 μm or less.

The pixels can take a known arrangement in plan view. Examples include a stripe arrangement, a delta arrangement (honeycomb arrangement), a PenTile arrangement, and a Bayer arrangement. The subpixel may have any known shape in plan view. Examples include quadrangles, such as a rectangle and a rhombus, and a hexagon. Of course, any incorrect rectangular shape is included in rectangles. A combination of the shape of the subpixel and a pixel arrangement may be employed.

### Application of Light-Emitting Element According to Embodiment

The light-emitting apparatus according to an embodiment can be used as a component of a display apparatus or the like. One example of the application is a light-emitting apparatus including a white light source with color filters.

The display apparatus may be an image information processing apparatus that includes an image input unit for receiving image information from an area charge-coupled device (CCD), a linear CCD, a memory card, or the like, an information processing unit for processing the input information, and a display unit for displaying the input image. The display unit may include the light-emitting apparatus according to any one of the first to fourth embodiments.

The display unit of an image capturing apparatus or an ink-jet printer may include the display apparatus according to any one of the first to fourth embodiments. The display unit may have a touch panel function. The drive method for the touch panel function may be, but is not limited to, of an infrared type, a capacitive type, a resistive type, or an electromagnetic induction type. The display apparatus may be used for the display unit of a multifunction printer.

Next, the display apparatus according to this embodiment will be described with reference to the drawings.

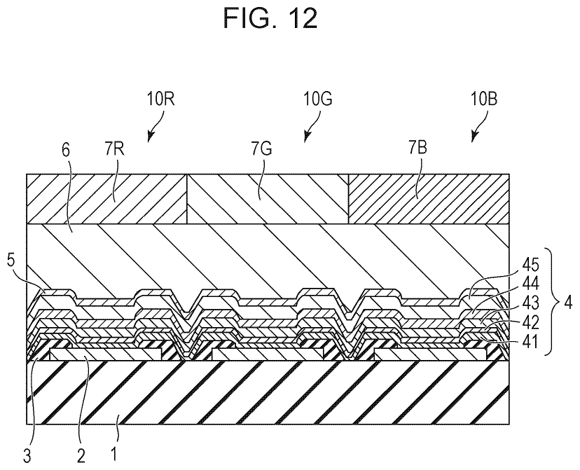

FIG. 12 is a schematic cross-sectional view of an example of a display apparatus including organic light-emitting elements and transistors connected to the organic light-emitting elements. The transistor is an example of active elements. In this example, the transistor is a thin-film transistor (TFT). Alternatively, MOSFETs using a semiconductor substrate may be used. Using the MOSFETs allows the transistors in each pixel to be arranged within a smaller area according to the embodiment.

FIG. 12 illustrates an example of a pixel, which is a component of the display apparatus according to this embodiment. The pixel includes subpixels 10. The subpixels 10 are divided into 10R, 10G, and 10B depending on the emission light. The emission colors may be distinguished by the wavelength of light emitted from the emission layer, or the light exiting from the subpixels 10 may be selectively transmitted or color-converted by color filters or similar means. Each subpixel 10 includes, on an inter-layer insulating layer 1, a reflecting electrode 2 (a first electrode), an insulating layer 3 covering the end of the reflecting electrode 2, an organic compound layer 4 covering the first electrode and the insulating layer, a transparent electrode 5, a protective layer 6, and a color filter 7.

The inter-layer insulating layer 1 may include transistors and capacitative elements thereunder or therein.

The transistors and the first electrodes may be each electrically connected via a contact hole (not shown).

The insulating layer 3 is also called a bank or a pixel isolating film. The insulating layer 3 covers the end of the first electrode to enclose the first electrode. The portion of the first electrode in which the insulating layer 3 is not disposed is in contact with the organic compound layer 4 to serve as a light-emitting area.

The organic compound layer 4 includes a hole injection layer 41, a hole transport layer 42, a first emission layer 43, a second emission layer 44, and an electron transport layer 45.

The second electrode 5 may be any of a transparent electrode, a reflecting electrode, and a semitransparent electrode.

The protective layer 6 reduces penetration of water into the organic compound layer 4. Although the protective layer 6 is a single layer in the drawing, it may have multiple layers. The protective layer 6 may include an inorganic compound layer and an organic compound layer.

The color filter 7 is divided into 7R, 7G, and 7B according to the color. The color filter 7 may be formed on a planarizing layer (not shown). A resin protective layer (not shown) may be provided on the color filter 7. The color filter 7 may be disposed on the protective layer 6. The color filter 7 may be disposed on the counter substrate such as a glass substrate, and then may be bonded together.

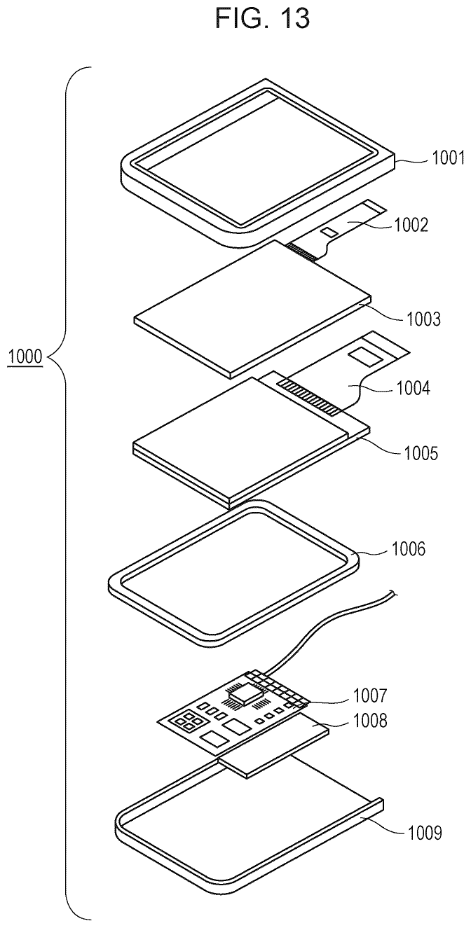

FIG. 13 is a schematic diagram illustrating an example of the display apparatus according to this embodiment. The display apparatus 1000 may include a touch panel 1003, a display panel 1005, a frame 1006, a circuit board 1007, and a battery 1008 between an upper cover 1001 and a lower cover 1009. The touch panel 1003 and the display panel 1005 connect to flexible printed circuits (FPCs) 1002 and 1004, respectively.

The display panel 1005 includes the light-emitting apparatuses according to at least one of the first to fourth embodiments. Transistors are printed on the circuit board 1007. The battery 1008 is not needed if the display apparatus is not a mobile device or may be disposed at another location if it is a mobile device.

The display apparatus according to this embodiment may include red, green, and blue color filters. The color filters may be arranged in a delta arrangement of red, green, and blue.

The display apparatus according to this embodiment may be used for the display unit of a mobile terminal. In this case, the display apparatus may include both of a display function and an operation function. Examples of the mobile terminal include mobile phones such as a smartphone, a tablet, and a head mount display.

The display apparatus according to this embodiment may be used for the display unit of an image capturing apparatus including an optical unit including multiple lenses and an image sensor that receives light passing through the optical unit. The image capturing apparatus may include a display unit that displays information captured by the image sensor. The display unit may be exposed out of the image capturing apparatus or disposed in the finder. The image capturing apparatus may be a digital camera or a digital video camera.

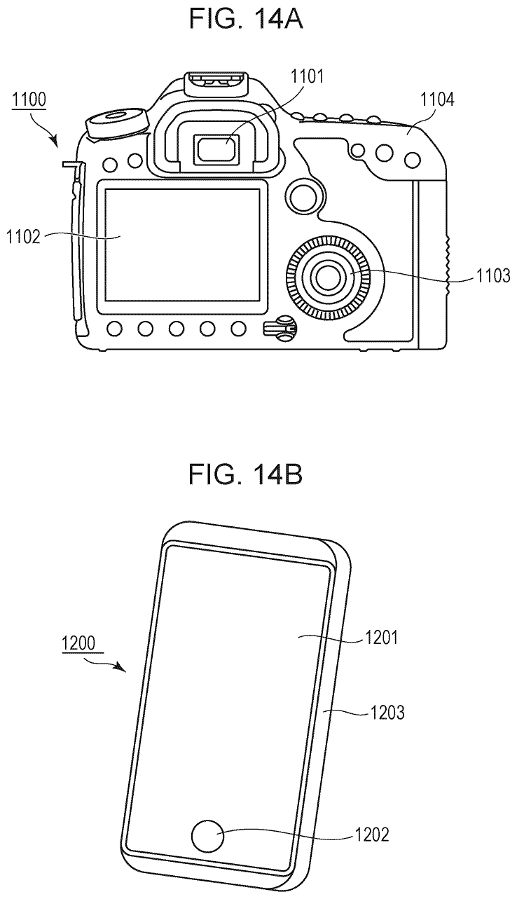

FIG. 14A is a schematic diagram illustrating an example of the image capturing apparatus according to this embodiment. The image capturing apparatus 1100 may include a viewfinder 1101, a back display 1102, an operating unit 1103, and a casing 1104. The viewfinder 1101 may include the light-emitting apparatus according to at least one of the first to fourth embodiments as a display. In this case, the light-emitting apparatus may display not only an image to be captured but also environmental information and image-capturing instructions. The environmental information may include the intensity and direction of outside light, the moving speed of the subject, and the possibility that the subject will be blocked by a shield.

The information should be displayed as fast as possible because the best timing for image capturing is short. Accordingly, the light-emitting apparatus according to at least one of the first to fourth embodiments including an organic light-emitting element may be used. This is because the organic light-emitting element has a fast response speed. In one embodiment, the display apparatus including the organic light-emitting element has high display speed. In this respect, the light-emitting apparatus according to any one of the first to fourth embodiments can be used more suitably than liquid crystal display apparatuses.

The image capturing apparatus 1100 includes an optical unit (not shown). The optical unit includes multiple lenses and forms an image on an image sensor housed in the casing 1104. The focus can be adjusted by modifying the relative positions of the multiple lenses. This operation can also be performed automatically. The image capturing apparatus may also be referred to as “photoelectric conversion apparatus”. The photoelectric conversion apparatus may include image capturing methods such as detecting differences from previous images and clipping images from continuously recorded images, instead of employing a sequential image capturing method.

FIG. 14B is a schematic diagram illustrating an example of the electronic apparatus according to this embodiment. The electronic apparatus 1200 includes a display unit 1201, an operating unit 1202, and a casing 1203. The casing 1203 may house a circuit, a printed board including the circuit, a battery, and a communication unit.

The display unit 1201 may include the light-emitting apparatus according to at least one of the first to fourth embodiments. The operating unit 1202 may be either a button or a touch panel type reaction unit. The operating unit 1202 may be a living-organism recognition unit that recognizes fingerprints to release the lock. The electronic apparatus including the communication unit can also be referred to as a communication apparatus. The electronic apparatus may further have a camera function by including a lens and an image sensor. An image captured using the camera function is displayed on the display unit. Examples of the electronic apparatus include a smartphone and a notebook personal computer (PC).

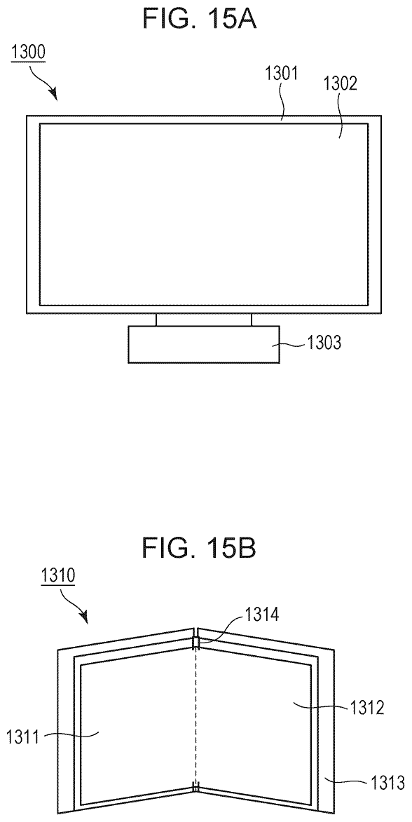

FIGS. 15A and 15B are schematic diagrams illustrating examples of the display apparatus according to this embodiment. FIG. 15A illustrates a display apparatus such as a television monitor or a PC monitor. The display apparatus 1300 includes a frame 1301 and a display unit 1302 enclosed by the frame 1301. The display unit 1302 may be the light-emitting apparatus according to at least one of the first to fourth embodiments.

The display apparatus 1300 further includes a base 1303 that supports the frame 1301 and the display unit 1302. The shape of the base 1303 is not limited to the shape shown in FIG. 15A. For example, the lower side of the frame 1301 may serve as the base.

The frame 1301 and the display unit 1302 may be curved. The radius of curvature may be 5,000 mm or more and 6,000 mm or less.

FIG. 15B is a schematic diagram illustrating another example of the display apparatus according to this embodiment. A display apparatus 1310 in FIG. 15B is a foldable display apparatus whose display surface is foldable. The display apparatus 1310 includes a first display unit 1311, a second display unit 1312, a casing 1313, and a folding point 1314. The first display unit 1311 and the second display unit 1312 may each include the light-emitting apparatus according to at least one of the first to fourth embodiments. The first display unit 1311 and the second display unit 1312 may constitute a seamless display apparatus. The first display unit 1311 and the second display unit 1312 can be divided by the folding point 1314. The first display unit 1311 and the second display unit 1312 may display either different images or one image.

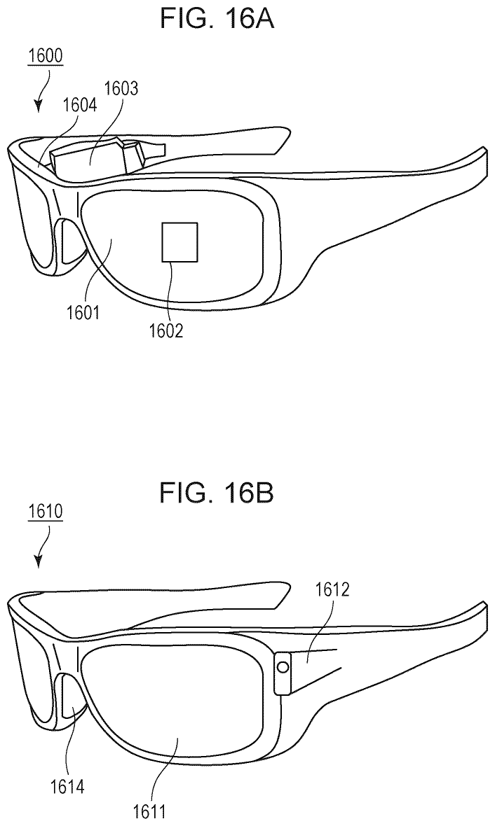

Referring to FIGS. 16A and 16B, applications of a display apparatus including the light-emitting apparatus according one of the first to fourth embodiments will be described. The display apparatus is applicable to wearable devices, such as smartglasses, head-mounted displays (HMDs), and smart contact lenses. Image capturing apparatuses and display apparatuses used in such applications may include an image capturing apparatus capable of photoelectrically converting visible light and a display apparatus capable of emitting visible light.

FIG. 16A illustrates a pair of glasses 1600 (smartglasses) according to an application. The pair of glasses 1600 includes an image capturing apparatus 1602, such as a complementary metal-oxide semiconductor (CMOS) sensor or a single photon avalanche diode (SPAD), on the front surface of a lens 1601. The display apparatus 1604 including the light-emitting apparatus according to at least one of the first to fourth embodiments is provided on the back of the lens 1601.

The pair of glasses 1600 further includes a control unit 1603. The control unit 1603 functions as a power source for supplying electricity to the image capturing apparatus 1602 and the display apparatus 1604. The control unit 1603 controls the operation of the image capturing apparatus 1602 and the display apparatus 1604. The lens 1601 is provided with an optical system for collecting light to the image capturing apparatus 1602.

FIG. 16B illustrates a pair of glasses (smartglasses) 1610 according to an application. The pair of glasses 1610 includes a control unit 1612. The control unit 1612 is provided with an image capturing apparatus corresponding to the image capturing apparatus 1602 and a display apparatus 1614 corresponding to the display apparatus 1604. A lens 1611 is provided with an optical system for projecting the light emitted from the display apparatus 1614 in the control unit 1612, and an image is projected on the lens 1611. The control unit 1612 functions as a power source for supplying electricity to the image capturing apparatus and the display apparatus 1614 and controls the operation of the image capturing apparatus and the display apparatus 1614.

The control units may include a gaze detection unit that detects the gaze of the wearer. The gaze detection may use infrared light. An infrared emission unit emits infrared light to the eyeball of a user who is looking at the displayed image. The image capturing unit including a light-receiving element detects the reflected light of the infrared light from the eyeball, so that an image of the eyeball is obtained. A reducing unit that reduces light from the infrared emission unit to the display unit in plan view reduces a decrease in image quality.

The gaze of the user to the displayed image is detected from the image of the eyeball captured using infrared light. The gaze detection using the captured image of the eyeball may use any known technique. An example is an eye-gaze tracking method based on Purkinje images obtained by the reflection of illuminated light on the cornea.

More specifically, a gaze tracking process based on pupil center corneal reflection is performed. The gaze of the user is detected by calculating a gaze vector indicating the orientation (rotation angle) of the eyeball on the basis the image of the pupil included in the captured image of the eyeball and Purkinje images using pupil center corneal reflection.

The pair of glasses 1610 according to an embodiment may include an image capturing apparatus including a light-receiving element and may control a display image of the display apparatus on the basis of user gaze information provided from the image capturing apparatus.

Specifically, for the display apparatus 1614, a first display area that the user gazes and a second display area other than the first display area are determined based on the gaze information. The first display area and the second display area may be determined by the control unit 1612 of the pair of glasses 1610 or may be received from an external control unit. In the display area of the display apparatus 1614, the display resolution of the first display area may be set higher than the display resolution of the second display area. In other words, the resolution of the second display area may be set lower than the resolution of the first display area.

The display area includes the first display area and the second display area different from the first display area. A higher priority area is determined from the first display area and the second display area based on the gaze information. The first display area and the second display area may be determined by the control unit of the display apparatus or may be received from an external control unit. The resolution of a higher priority area may be set higher than the resolution of the area other than the higher priority area. In other words, the resolution of the lower priority area may be set low.

The determination of the first display area and the higher priority area may use artificial intelligence (AI). The AI may be a model configured to estimate the angle of the gaze and the distance to the object of the gaze from an image of the eyeball using the image of the eyeball and the direction in which the eyeball in the image gazes actually as training data. The AI program may be installed in the display apparatus, the image capturing apparatus, or an external apparatus. The AI program, if installed in an external apparatus, is sent to the display apparatus via communication.

Display control based on visual recognition allows application to smartglasses that further includes an image capturing apparatus that captures an external image. Smartglasses can display the captured external information in real time.

Thus, by applying the light-emitting apparatus according to at least one of the first to fourth embodiments to various apparatuses according to the embodiments, the minimization or high definition of the apparatuses with the same size can be achieved, and manufacturing variations of the apparatuses can be reduced.

Thus, the embodiments allow miniaturization of the pixel drive circuits of the light-emitting apparatuses, thereby achieving the high definition and miniaturization of the light-emitting apparatuses.

While the disclosure has been described with reference to exemplary embodiments, it is to be understood that the disclosure is not limited to the disclosed exemplary embodiments. The scope of the following claims is to be accorded the broadest interpretation so as to encompass all such modifications and equivalent structures and functions.

This application claims the benefit of Japanese Patent Application No. 2024-038092, filed Mar. 12, 2024, which is hereby incorporated by reference herein in its entirety.

What is claimed is:

1. A light-emitting apparatus comprising:
a plurality of pixels each including a plurality of subpixels,
wherein the plurality of pixels includes a first pixel and a second pixel adjacent to each other in a first direction and a third pixel and a fourth pixel adjacent to each other in the first direction,
wherein the first pixel and the second pixel are adjacent to the third pixel and the fourth pixel, respectively, in a second direction crossing the first direction,
wherein the plurality of subpixels each includes:
a light-emitting element disposed over a main surface of a substrate;
a drive transistor connected to the light-emitting element;
a write transistor connected to the drive transistor; and
a first capacitive element disposed between a source or a drain and a gate of the drive transistor,
wherein the plurality of subpixels each includes a first subpixel, a second subpixel, and a third subpixel disposed between the first subpixel and the second subpixel in the first direction,
wherein, in each of the first subpixel and the second subpixel, the gate of the drive transistor is larger than a gate of the write transistor, in a plan view,
wherein the first subpixel of the first pixel and the second subpixel of the second pixel are adjacent to each other in the first direction,
wherein the first subpixel of the third pixel and the second subpixel of the fourth pixel are adjacent to each other in the first direction.

2. The light-emitting apparatus according to claim 1,
wherein, in the first pixel, the gate of the drive transistor of the first subpixel and the gate of the drive transistor of the third subpixel do not overlap with each other in the first direction,
wherein the gate of the drive transistor of the first subpixel of the first pixel and the gate of the drive transistor of the second subpixel of the second pixel do not overlap with each other in the first direction, and
wherein the gate of the drive transistor of the first subpixel of the third pixel and the gate of the drive transistor of the second subpixel of the fourth pixel do not overlap with each other in the first direction.

3. The light-emitting apparatus according to claim 2, wherein, a direction from the source to the drain of the drive transistor is the same between the first pixel and the second pixel.

4. The light-emitting apparatus according to claim 2, wherein the plurality of subpixels each includes an emission control transistor disposed between a first power supply line and the drive transistor and a second capacitive element disposed between a source and a drain of the emission control transistor; and
wherein, in the first pixel and the second pixel, the gate of the drive transistor in the plan view is larger than a gate of the emission control transistor in the plan view.

5. The light-emitting apparatus according to claim 2, wherein a gate of the write transistor in the first pixel and a gate of the write transistor in the second pixel overlap with each other at least partly in the first direction.

6. The light-emitting apparatus according to claim 4,
wherein the plurality of pixels includes the third subpixel disposed between the first subpixel and the second subpixel; and
wherein a gate of the emission control transistor of the first subpixel of the first pixel and a gate of the emission control transistor of the third subpixel of the second pixel overlap with each other at least partly in the first direction.

7. The light-emitting apparatus according to claim 6, wherein, the plurality of subpixels each includes a reset transistor in which one of a source and a drain is connected to the light-emitting element and the emission control transistor, and another of the source and the drain is connected to a second power supply line.

8. The light-emitting apparatus according to claim 7, wherein, in the first pixel and the second pixel, the gate of the drive transistor in the plan view is larger than a gate of the reset transistor in the plan view.

9. The light-emitting apparatus according to claim 7,
wherein the plurality of pixels each include the third subpixel disposed between the first subpixel and the second subpixel; and
wherein the gate of the drive transistor of the first subpixel of the first pixel is disposed between a gate of the emission control transistor of the third subpixel of the first pixel and a gate of the emission control transistor of the second subpixel of the second pixel in the first direction.

10. The light-emitting apparatus according to claim 7,
wherein the plurality of pixels each include the third subpixel disposed between the first subpixel and the second subpixel; and
wherein the gate of the emission control transistor of the first subpixel of the first pixel is disposed between a gate of the write transistor of the third subpixel of the first pixel and a gate of the write transistor of the first subpixel of the first pixel in the first direction.

11. The light-emitting apparatus according to claim 7, wherein, in the first subpixel of the first pixel, the gate of the drive transistor is disposed between a gate of the emission control transistor and a gate of the reset transistor in the second direction.

12. The light-emitting apparatus according to claim 11, wherein a gate of the reset transistor of the second subpixel of the second pixel overlaps with the gate of the reset transistor of the first subpixel of the first pixel at least partly in the second direction.

13. A photoelectric conversion apparatus comprising:
an optical unit including a plurality of lenses;
an image sensor that receives light that has passed through the optical unit; and
a display unit that displays an image captured by the image sensor,
wherein the display unit includes the light-emitting apparatus according to claim 1.

14. The photoelectric conversion apparatus according to claim 13, wherein, in the light-emitting apparatus,
the first pixel, the gate of the drive transistor of the first subpixel and the gate of the drive transistor of the third subpixel do not overlap with each other in the first direction,
the gate of the drive transistor of the first subpixel of the first pixel and the gate of the drive transistor of the second subpixel of the second pixel do not overlap with each other in the first direction, and
the gate of the drive transistor of the first subpixel of the third pixel and the gate of the drive transistor of the second subpixel of the fourth pixel do not overlap with each other in the first direction.

15. An electronic apparatus comprising:
a display unit including the light-emitting apparatus according to claim 1;
a casing including the display unit; and
a communication unit provided at the casing, the communication unit being configured to communicate with outside.

16. The electronic apparatus according to claim 15, wherein, in the light-emitting apparatus,
the first pixel, the gate of the drive transistor of the first subpixel and the gate of the drive transistor of the third subpixel do not overlap with each other in the first direction,
the gate of the drive transistor of the first subpixel of the first pixel and the gate of the drive transistor of the second subpixel of the second pixel do not overlap with each other in the first direction, and
the gate of the drive transistor of the first subpixel of the third pixel and the gate of the drive transistor of the second subpixel of the fourth pixel do not overlap with each other in the first direction.

17. A pair of glasses comprising:
a lens including an image capturing apparatus and a display unit; and
a control unit,
wherein the display unit includes the light-emitting apparatus according to claim 1, and
wherein the control unit controls the operation of the image capturing apparatus and the light-emitting apparatus.

18. The pair of glasses according to claim 17, wherein, in the light-emitting apparatus,
the first pixel, the gate of the drive transistor of the first subpixel and the gate of the drive transistor of the third subpixel do not overlap with each other in the first direction,
the gate of the drive transistor of the first subpixel of the first pixel and the gate of the drive transistor of the second subpixel of the second pixel do not overlap with each other in the first direction, and
the gate of the drive transistor of the first subpixel of the third pixel and the gate of the drive transistor of the second subpixel of the fourth pixel do not overlap with each other in the first direction.
